(19) United States
(12) Patent Application Publication
(10) Pub. No.: US 2026/0101828 A1
(43) Pub. Date: Apr. 9, 2026

(54) SEMICONDUCTOR MODULE

(71) Applicant: RESEARCH ASSOCIATION FOR ADVANCED SYSTEMS, Tokyo (JP)

(72) Inventors: Atsutake KOSUGE, Tokyo (JP); Tadahiro KURODA, Tokyo (JP)

(21) Appl. No.: 19/405,996

(22) Filed: Dec. 2, 2025

Related U.S. Application Data
(63) Continuation of application No. PCT/JP2024/018676, filed on May 21, 2024.

(30) Foreign Application Priority Data
Jun. 20, 2023 (JP) 2023-101092

(51) Int. Cl. H10W 90/10; H10B 80/00; H10W 44/00; H10W 90/00; H10W 90/28

(52) U.S. Cl. CPC H10W 90/10; H10B 80/00; H10W 44/501; H10W 90/28; H10W 90/724; H10W 90/792

(57) ABSTRACT

A semiconductor module includes a first logic chip including a first surface and a second surface parallel to a first direction and a second direction, a first semiconductor chip including a third surface and a fourth surface, arranged on the second surface, and connected to the first logic chip, and a semiconductor cube arranged on the fourth surface, the semiconductor cube including a plurality of second semiconductor chips stacked in the first direction. The second semiconductor chip includes a first inductor arranged in a third direction perpendicular to the first and second directions, and the first semiconductor chip includes a plurality of routers and a second inductor arranged parallel to the fourth surface. The plurality of circuits in the first logic chip and the plurality of circuits in the first semiconductor chip are connected using the plurality of routers, and enable contactless communication with the plurality of second semiconductor chips.

### CROSS-REFERENCE TO RELATED APPLICATIONS

This application is a Continuation of International Patent Application No. PCT/JP2024/018676, filed on May 21, 2024, which claims the benefit of priority to Japanese Patent Application No. 2023-101092, filed on Jun. 20, 2023, the entire contents of which are incorporated herein by reference.

### FIELD

An embodiment of the present invention relates to a semiconductor module.

### BACKGROUND

In recent years, power consumption of electronic computers such as data centers has rapidly increased. In addition, with an increase in the amount of data communication, the power consumption of an electronic computer is rapidly increased, the memory capacity of the electronic computer is increased, and the demand for reduction in power consumption and increase in capacity of the electronic computer is increasing. For example, the electronic computer includes a plurality of logic chips and a plurality of memory chips electrically connected to the plurality of logic chips. The logic chip is, for example, a semiconductor chip on which a logic circuit is mounted, and the memory chip is a semiconductor chip on which a memory circuit is mounted. Data communication in an electronic computer is performed between a logic chip and a memory chip, for example. For example, reducing a distance between the logic chip and the memory chip by stacking and three-dimensionally mounting the logic chip and the memory chip is one effective solution for reducing the power consumption of the electronic computer.

As an example of a three-dimensional mounting method, a semiconductor module in which a structure (vertically stacked memory cube) in which a plurality of memory chips is stacked is arranged on a substrate or a logic chip such that the plurality of memory chips is parallel to the substrate or the logic chip, or a semiconductor module in which a structure (horizontally stacked memory cube) in which a plurality of memory chips is stacked is vertically placed on a substrate or a logic chip such that the plurality of memory chips is perpendicular to the substrate or the logic chip is known. The vertically stacked memory cube and the substrate or the logic chip are electrically connected to each other using, for example, a TSV, a microbump, or the like. Further, a technique of performing contactless communication between a chip and a substrate is known.

### SUMMARY

A semiconductor module includes a first logic chip including a first surface parallel to a first direction and a second direction intersecting the first direction, and a second surface parallel to the first surface, a first semiconductor chip including a third surface parallel to the second surface and a fourth surface parallel to the third surface, the third surface being arranged on the second surface, and electrically connected to the first logic chip, and a first semiconductor cube including a plurality of second semiconductor chips stacked in the first direction, and arranged on the fourth surface. Each of the plurality of second semiconductor chips may include a first inductor arranged in a third direction perpendicular to the first and second directions. The first semiconductor chip may include a plurality of routers and a second inductor arranged parallel to the fourth surface. A plurality of circuits in the first logic chip and a plurality of circuits in the first semiconductor chip may be connected using the plurality of routers. The plurality of second semiconductor chips, the first logic chip, and the first semiconductor chip may be configured to enable contactless communication using the first inductor and the second inductor.

In the semiconductor module, the first logic chip may include a first electrode on the second surface, and the first semiconductor chip may include a second electrode. The second electrode may be configured so as to join the first electrode by fusion bonding on the third surface.

In the semiconductor module, each of the plurality of routers may include a switch.

In the semiconductor module, the plurality of second semiconductor chips may include at least one type of memory chip. The first semiconductor chip may include a memory controller configured to control the at least one type of memory chip.

In the semiconductor module, the plurality of second semiconductor chips may include an FPGA chip configured to be controllable using the first logic chip.

In the semiconductor module, the first logic chip may include a plurality of wiring layers provided on the first surface side, may be electrically connected to a package substrate via a plurality of bumps electrically connected to the plurality of wiring layers, and may receive a control signal and a power supply voltage from the package substrate.

In the semiconductor module, the first logic chip may be connected to the third surface of the first semiconductor chip in a face-up connection. The first semiconductor chip may be electrically connected to the first semiconductor cube in a face-up connection.

The semiconductor module may include a second logic chip different from the first semiconductor chip, the second semiconductor chip, and the first logic chip. The second logic chip may include a sixth surface parallel to the first direction and the second direction and a seventh surface parallel to the sixth surface, and may be arranged spaced apart from the first logic chip in the first direction and the second direction. The sixth surface may be in contact with the third surface.

The semiconductor module may include a second semiconductor cube on which a plurality of third semiconductor chips different from the first semiconductor chip, the second semiconductor chip, and the first logic chip are arranged in the first direction. The second semiconductor cube may be arranged on a fifth surface of the first semiconductor cube opposite the fourth surface along the third direction.

### BRIEF DESCRIPTION OF DRAWINGS

FIG. 1 is a perspective view showing a configuration of a semiconductor module according to a first embodiment of the present invention.

FIG. 2 is a cross-sectional view showing the configuration of the semiconductor module according to the first embodiment of the present invention.

FIG. 3A is a perspective view showing an inductor group included in a plurality of memory chips and an inductor group included in a magnetic field coupling chip interface router chip (Through Chip Interface Router Chip (TCI router chip)) according to the first embodiment of the present disclosure.

FIG. 3B is a perspective view showing a configuration of the inductor on the memory chip and the inductor on the TCI router chip shown in FIG. 3A.

FIG. 4 is a schematic diagram showing configurations of a memory cube and the TCI router chip according to the first embodiment of the present disclosure.

FIG. 5 is a schematic diagram showing configurations of the TCI router chip and a logic chip according to the first embodiment of the present disclosure.

FIG. 6 is a schematic diagram showing a configuration of the memory chip according to the first embodiment of the present invention.

FIG. 7 is a perspective view showing the configuration of the memory chip according to the first embodiment of the present invention.

FIG. 8 is a cross-sectional view showing a cross-sectional structure of the memory chip taken along a line A1-A2 shown in FIG. 7.

FIG. 9 is a schematic diagram showing the configuration of the TCI router chip according to the first embodiment of the present invention.

FIG. 10 is a perspective view showing the configuration of the TCI router chip according to the first embodiment of the present invention.

FIG. 11 is a cross-sectional view showing a cross-sectional structure of the TCI router chip taken along a line B1-B2 shown in FIG. 9.

FIG. 12 is a schematic diagram showing the configuration of the logic chip according to the first embodiment of the present invention.

FIG. 13 is a perspective view showing the configuration of the logic chip according to the first embodiment of the present invention.

FIG. 14 is a cross-sectional view showing a cross-sectional structure of the logic chip taken along a line C1-C2 shown in FIG. 12.

FIG. 15 is a cross-sectional view showing a configuration of a semiconductor module according to a second embodiment of the present invention.

FIG. 16 is a schematic diagram showing a configuration of a memory cube and a TCI router chip according to the second embodiment of the present invention.

FIG. 17 is a cross-sectional view showing a configuration of a semiconductor module according to a third embodiment of the present invention.

FIG. 18 is a schematic diagram showing a configuration of a FPGA cube and a TCI router chip according to the third embodiment of the present invention.

FIG. 19 is a cross-sectional view showing a configuration of a semiconductor module according to a fourth embodiment of the present invention.

FIG. 20 is a schematic diagram showing a configuration of a memory cube and a TCI router chip according to the fourth embodiment of the present invention.

FIG. 21 is a cross-sectional view showing a configuration of a semiconductor module according to a fifth embodiment of the present invention.

FIG. 22 is a cross-sectional view showing a configuration of a semiconductor module according to a sixth embodiment of the present invention.

### DESCRIPTION OF EMBODIMENTS

For example, since a memory chip, a substrate, and a logic chip of a well-known semiconductor module are stacked in parallel in a stacking direction, thermal resistance of the semiconductor module associated with an oxide film included in a plurality of stacked memory chips increases. When the thermal resistance of the semiconductor module increases, thermal conductivity of the semiconductor module decreases, and for example, it becomes difficult to heat the logic chip. When it becomes difficult to heat the logic chip, temperature of the semiconductor module rises, which may cause malfunction of the semiconductor module. Further, in order to suppress the malfunction of the semiconductor module, it is necessary to suppress the temperature rise of the semiconductor module to a temperature range in which the semiconductor module operates normally. Therefore, the number of stacked chips in the semiconductor module is limited.

Further, a logic chip of a well-known semiconductor module is connected to an external circuit by using a redistribution layer. As a result, a length of a wiring and a wiring load (capacitance) increase, and a signal transmission delay occurs, calculation performance deteriorates, and power consumption of the chip increases.

Further, in the well-known technique, although a gap is formed between a chip and a substrate, the chip and the substrate are arranged at positions adjacent to each other. As a result, electromagnetic noise caused by contactless communication between the chip and the substrate is generated, and the chip and the substrate may malfunction due to electromagnetic noise.

In view of the above problems, an object of an embodiment of the present invention is to provide a semiconductor module using inductor communication capable of suppressing signal delay and reducing power consumption while being excellent in heat conduction and excellent in heat removal characteristics and suppressing malfunction caused by electromagnetic noise and heat.

Hereinafter, embodiments of the present invention will be described with reference to the drawings and the like. However, the present invention can be implemented in many different aspects, and should not be construed as being limited to the description of the embodiments exemplified below. In order to make the description clearer, the drawings may be schematically represented with respect to the width, thickness, shape, and the like of each part as compared with the actual embodiment. However, the drawings are merely examples, and do not limit the interpretation of the present invention. In addition, in the present specification and the drawings, the same reference signs (or reference signs with a, b, and the like added after the number) are given to the same elements as those described above with respect to the previous drawings, and detailed description thereof may be omitted as appropriate. Furthermore, the terms “first” and “second” with respect to the respective elements are convenient signs used to distinguish the respective elements, and do not have any further meaning unless otherwise specified.

In one embodiment of the invention, in the case where a member or region is “above (or below)” another member or region, this includes not only a case where it is directly above (or directly below) the other member or region, unless otherwise limited, but also a case where it is above (or below) the other member or region, that is, a case where another component is included between above (or below) the other member or region.

In an embodiment of the present disclosure, a direction D1 intersects a direction D2, and a direction D3 intersects the direction D1 and the direction D2 (a plane D1D2). The direction D1 is referred to as a first direction, the direction D2 is referred to as a second direction, and the direction D3 is referred to as a third direction.

In one embodiment of the present invention, in the case where the terms “identical” and “matching” are used, the terms “identical” and “matching” may include a margin of error within the design range. In addition, in an embodiment of the present invention, in the case where an error in the range of design is included, the expressions “substantially identical”and “substantially matching”may be used in some cases.

### FIRST EMBODIMENT

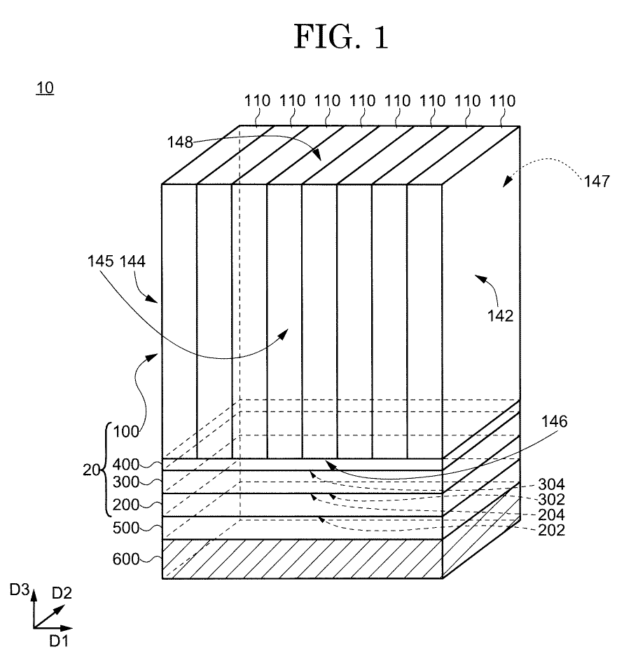

A semiconductor module 10 according to the first embodiment will be described with reference to FIG. 1 to FIG. 14.

### [1-1. Overview of Semiconductor Module 10]

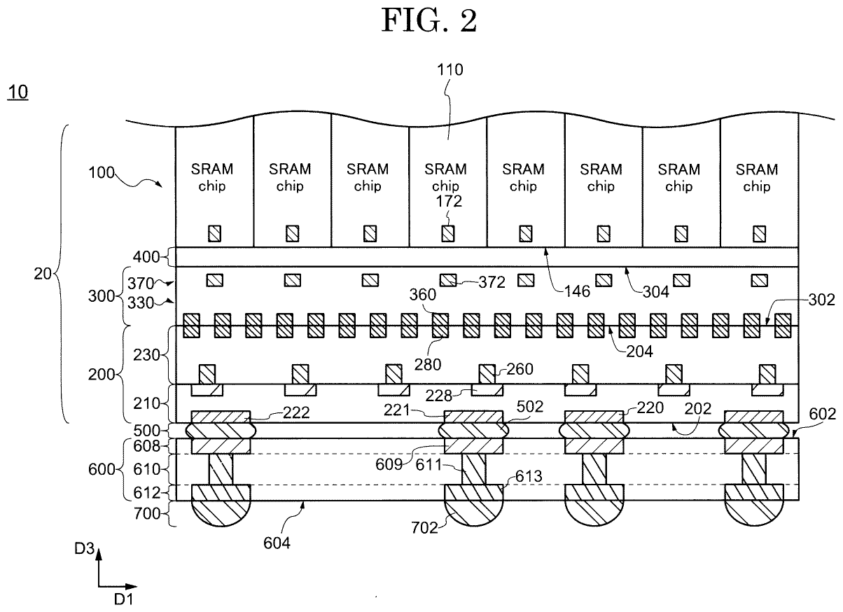

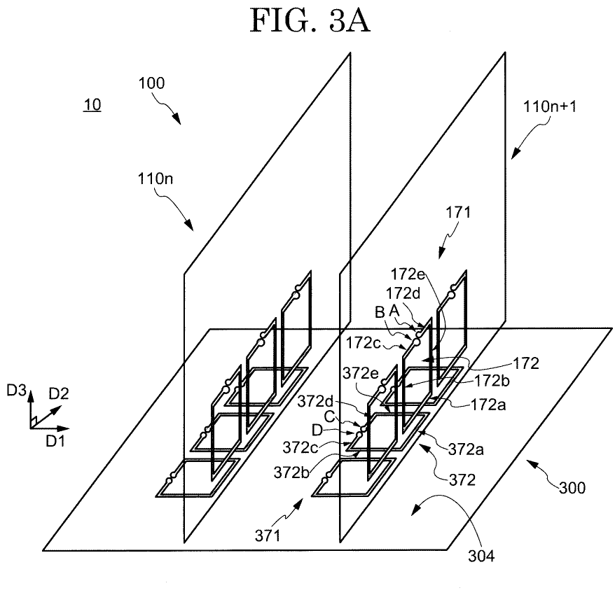

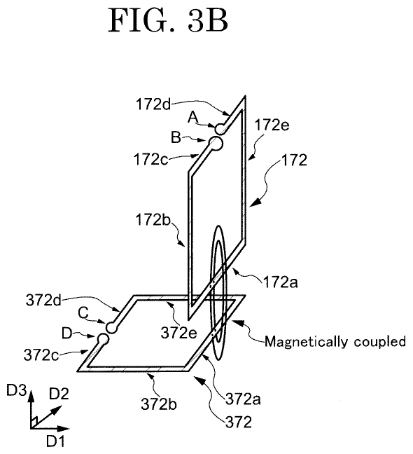

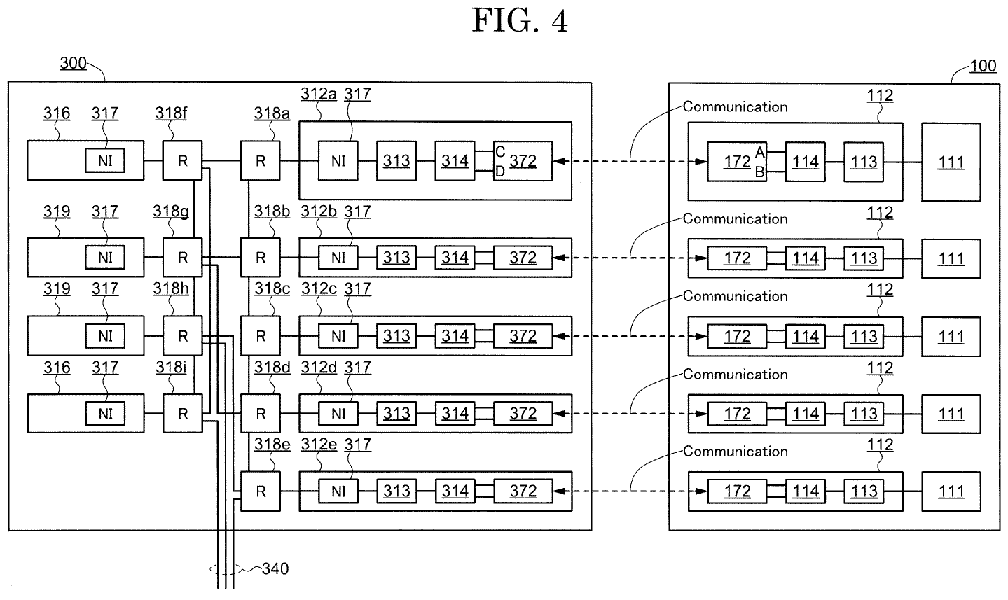

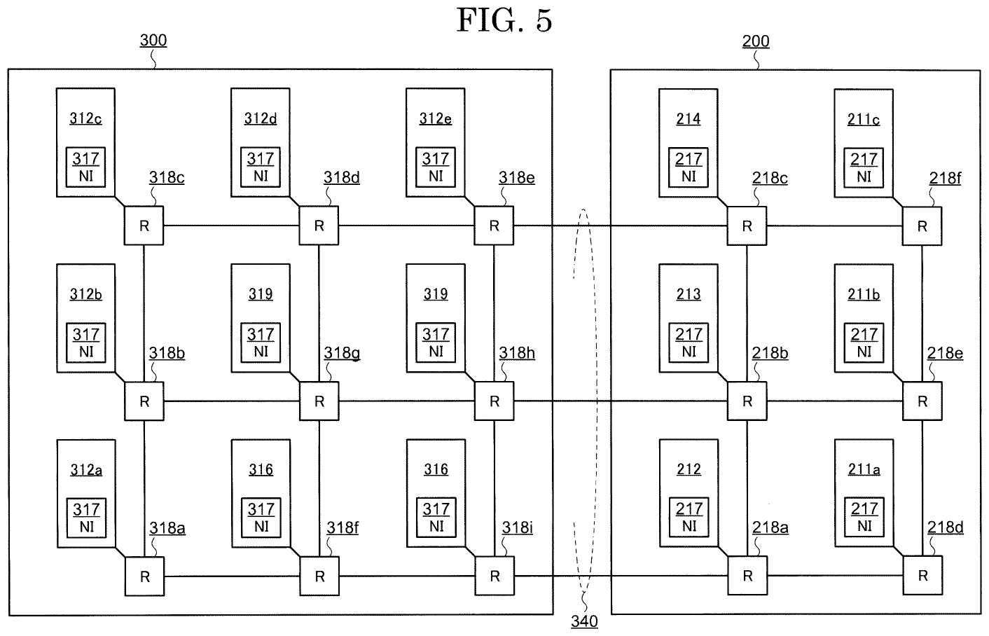

An overview of the semiconductor module 10 will be described with reference to FIG. 1 to FIG. 5. FIG. 1 is a perspective view showing a configuration of the semiconductor module 10. FIG. 2 is a cross-sectional view showing the configuration of the semiconductor module 10. FIG. 3A is a perspective view showing an inductor group 171 included in a plurality of memory chips 110 included in the semiconductor module 10, and an inductor group 371 included in a magnetic field coupling chip interface router chip (Through Chip Interface Router Chip (TCI router chip)) 300, and FIG. 3B is a perspective view showing a configuration of an inductor 172 on the memory chip 110 and an inductor 372 on the TCI router chip 300 shown in FIG. 3A. FIG. 4 is a schematic diagram showing a configuration of a memory cube 100 and the TCI router chip 300 included in the semiconductor module 10. FIG. 5 is a schematic diagram showing the configuration of the TCI router chip 300 and a logic chip 200 included in the semiconductor module 10.

### [1-1-1. Overall Configuration of Semiconductor Module 10]

An overall configuration of the semiconductor module 10 will be described with reference to FIG. 1 and FIG. 2.

As shown in FIG. 1 or FIG. 2, the semiconductor module 10 includes the memory cube 100, the TCI router chip 300, the logic chip 200, and an adhesive layer 400. For example, a stacked body 20 includes the memory cube 100, the TCI router chip 300, the logic chip 200, and the adhesive layer 400. The semiconductor module 10 may include a bump layer 500, a package substrate 600, and a bump layer 700. The memory cube 100 may be referred to as a first semiconductor cube, the TCI router chip 300 may be referred to as a first semiconductor chip, and the logic chip 200 may be referred to as a first logic chip.

The memory cube 100 includes a configuration in which the plurality of memory chips 110 are stacked in the direction D1. Each of the plurality of memory chips 110 has a similar configuration including a plurality of inductors 172 (first inductors). The memory cube 100 includes a first surface 142 parallel to the directions D2 and D3 and a second surface 144 opposite the first surface 142 and parallel to the first surface 142 with respect to the direction D1. The memory cube 100 also includes a first side surface 145 that is perpendicular to the first surface 142 and the second surface 144, a second side surface 146 that is adjacent to the first side surface 145, a third side surface 147 that is adjacent to the second side surface 146, and a fourth side surface 148 that is adjacent to the third side surface 147 and the first side surface 145. The second side surface 146 is positioned so as to be in contact with the adhesive layer 400 and face a second surface 304 of the TCI router chip 300, and the memory cube 100 is arranged on the second surface 304 of the TCI router chip 300. The memory chip 110 may be referred to as a second semiconductor chip. The plurality of inductors 172 is parallel to and spaced apart from the second side surface 146 and arranged side by side in the direction D2.

In the case where each of the plurality of memory chips 110 is indistinguishable, the memory chip is represented as the memory chip 110. In the case where each of the plurality of memory chips 110 is distinguished, the memory chip is represented as a memory chip 110n, a memory chip 110n+1, or the like. The plurality of memory chips 110 included in the memory cube 100 includes, for example, the memory chip 110n (see FIG. 3A or FIG. 3B) and the memory chip 110n+1 (see FIG. 3 or FIG. 3B) arranged adjacent to the memory chip 110n. In addition, the memory cube 100 includes a configuration in which eight layers of memory chips 110 are stacked in the direction D1. The number of stacked memory chips 110 shown in FIG. 1 is an example, and the number of stacked memory chips 110 is not limited to the eight layers shown in FIG. 1. The number of stacked memory chips 110 may be appropriately selected based on the use, specifications, and the like of the semiconductor module 10.

The TCI router chip 300 includes, for example, a transistor layer 330 and an inductor layer 370 stacked on the transistor layer 330. The transistor layer 330 includes a first surface 302, which is an exposed surface of the TCI router chip 300, and a plurality of through electrodes 360. The plurality of through electrodes 360 is exposed to the first surface 302. The inductor layer 370 includes the second surface 304, which is an exposed surface of the TCI router chip 300 opposing the first surface 302, and a plurality of inductors 372. The first surface 302 and the second surface 304 are surfaces parallel to the direction D1 and the direction D2. The first surface 302 is positioned to face a second surface 204 of the logic chip 200 and is in contact with the second surface 204 of the logic chip 200. Further, as described above, the second surface 304 is positioned so as to be in contact with the adhesive layer 400 and face the second side surface 146 of the memory cube 100. The TCI router chip 300 includes a wiring layer 350 between the transistor layer 330 and the inductor layer 370. The transistor layer 330, the wiring layer 350, and the inductor layer 370 are stacked in this order in the direction D3.

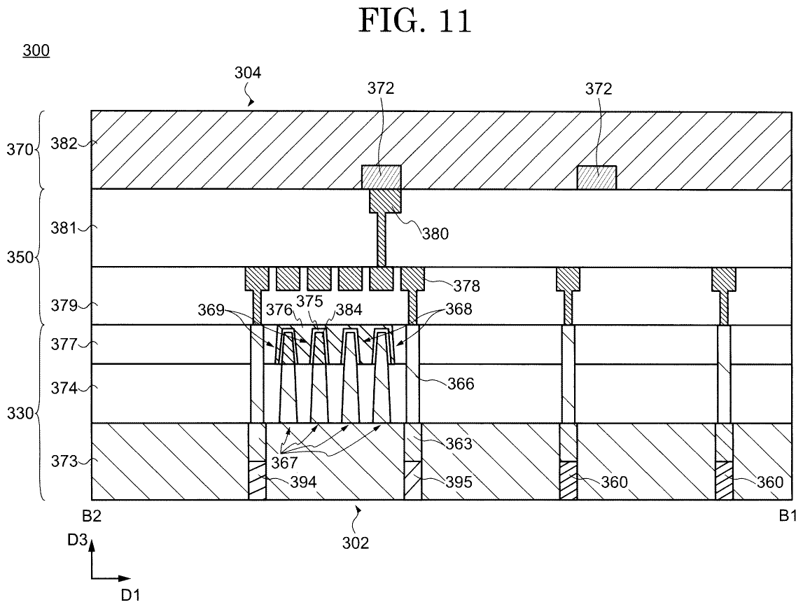

Further, although the details will be explained later, a substrate 373 (for example, see FIG. 11) included in the TCI router chip 300 is positioned below the direction D3 (toward the first surface 302), and an N-type transistor 368 and a P-type transistor 369 (see, for example, FIG. 11) are stacked above the substrate 373 with respect to the direction D3. That is, the stacking direction of the layers constituting the TCI router chip 300 is upward in the direction D3. For example, a mounting structure in which a stacking direction is upward in the direction D3 is called face-up mounting, and a mounting structure in which a stacking direction is downward in the direction D3 is called face-down mounting. The first surface 302 of the TCI router chip 300 is arranged on the logic chip 200, and the TCI router chip 300 is face-up mounted, in the semiconductor module 10.

The logic chip 200 includes, for example, a lower wiring layer 210 and a transistor layer 230 stacked on the lower wiring layer 210. The lower wiring layer 210 includes a first surface 202 that is an exposed surface of the logic chip 200, a plurality of electrode pads 222, 221, and 220, and a plurality of wirings 228. The plurality of electrode pads 222, 221, and 220 are exposed to the first surface 202. The transistor layer 230 includes the second surface 204, which is an exposed surface of the logic chip 200 opposite to the first surface 202, a plurality of through electrodes 260 connected to the plurality of wirings 228, respectively, and a plurality of wirings 280. The plurality of wirings 280 is exposed on the second surface 204. The first surface 202 and the second surface 204 are surfaces parallel to the direction D1 and the direction D2. The second surface 204 is a surface in contact with the first surface 302 of the TCI router chip 300. In addition, the logic chip 200 is arranged on the package substrate 600 via, for example, the bump layer 500 arranged on the first surface 202.

Further, the second surface 204 of the logic chip 200 is arranged to face the first surface 302 of the TCI router chip 300, and the logic chip 200 is stacked (bonded) with the TCI router chip 300. In this case, each of the plurality of wirings 280 is joined to the corresponding plurality of through electrodes 360, and the logic chip 200 is electrically connected to the TCI router chip 300. For the stacking (bonding) of the chips, for example, a technique such as welding (fusion bonding (Fusion Bonding)) or silicon-direct bonding (Silicon Direct Bonding (SDB)) can be used. Since welding and silicon direct bonding are well known in the art, detailed description is omitted here. In addition, the plurality of wirings 280 and the plurality of through electrodes 360 are formed using, for example, a conductor made of metal. The conductor made of metal is, for example, a conductor containing copper or the like. Each of the wiring 280 and the through electrode 360 may be referred to as, for example, a first electrode and a second electrode.

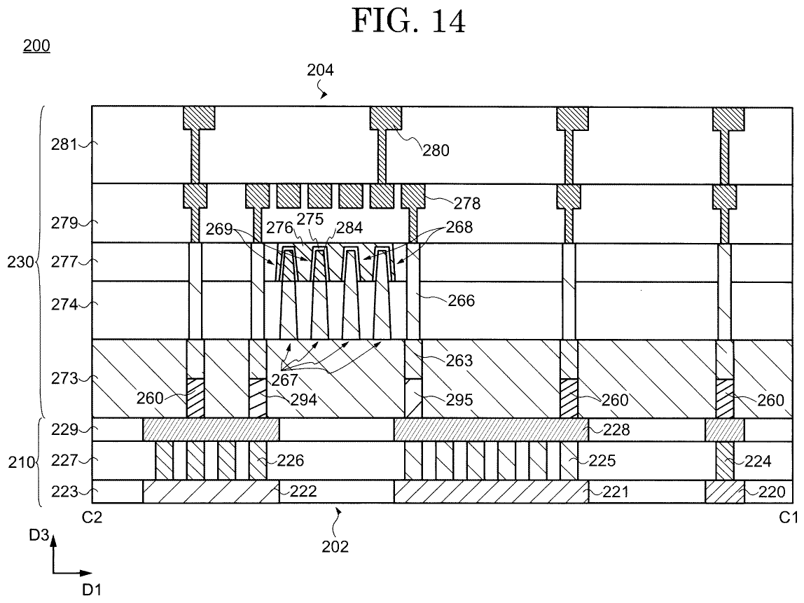

Further, as will be described later, a substrate 273 (see, for example, FIG. 14) included in the logic chip 200 is positioned downward (toward the first surface 202) with respect to the direction D3, and an N-type transistor 268 and a P-type transistor 269 (see, for example, FIG. 14) are stacked above the substrate 273 with respect to the direction D3. The first surface 202 of the logic chip 200 is arranged on the package substrate 600, and the logic chip 200 is face-up mounted on the package substrate 600, in the semiconductor module 10.

The adhesive layer 400 is arranged between the memory cube 100 and the TCI router chip 300 to adhere the memory cube 100 and the TCI router chip 300. The adhesive layer 400 may be, for example, an adhesive containing an epoxy resin, an acrylic polymer, or the like, a die bonding film (Die Bonding Film (DBF)) containing an epoxy resin or an acrylic polymer, an adhesive film such as a die attach film (Die Attached Film (DAF)), or the like.

The package substrate 600 includes a multilayer wiring structure in which wirings and insulating layers are alternately stacked, and the package substrate 600 includes, for example, a second surface 604 and a first surface 602, which are exposed surfaces of the package substrate 600, and a plurality of wiring layers 608, 610, and 612. The wiring layers 608, 610, and 612 are arranged in the direction D1 and the direction D2, and are stacked in this order from top to bottom in the direction D3. The plurality of wiring layers 608, 610, and 612 include a plurality of wirings 609, a plurality of wirings 611, and a plurality of wirings 613. The plurality of wirings 609 is exposed to the first surface 602, and the plurality of wirings 613 is exposed to the second surface 604. For example, the wiring 609 is electrically connected to the wiring 611, and the wiring 611 is electrically connected to the wiring 613. In FIG. 2, insulating layers alternately stacked with the wiring are not shown. The number of stacked layers of the multilayer wiring structure of the package substrate 600 is not limited to the number of stacked layers (three layers) shown in FIG. 2. The number of layers of the multilayer wiring structure of the package substrate 600 can be appropriately changed based on the application or specification of the semiconductor module 10.

Further, the package substrate 600 is electrically connected to the stacked body 20 via a plurality of bumps 502 included in the bump layer 500 arranged between the stacked body 20 and the package substrate 600. The package substrate 600 is connected to an external substrate, an external circuit, and the like via a plurality of bumps 702 included in the bump layer 700. Specifically, each of the plurality of wirings 609 exposed on the first surface 602 is electrically connected to each of the plurality of electrode pads 222, 221, and 220 included in the logic chip 200 by using the bump 502, and each of the plurality of wirings 613 exposed on the second surface 604 is connected to an external substrate, an external circuit, or the like by using the bump 702.

The semiconductor module 10 includes the memory cube 100 vertically placed on the TCI router chip 300 in the direction D3, and has a lower thermal resistivity than a configuration including a plurality of memory chips stacked in the direction D1 and the direction D2. Therefore, since the semiconductor module 10 has high thermal conductivity and excellent heat removal characteristics, it is possible to suppress malfunction caused by temperature rise of the semiconductor module. Therefore, limitation of the number of stacked chips in the semiconductor module 10 is relaxed compared to the configuration including the plurality of memory chips stacked in the direction D1 and the direction D2.

### [1-1-2. Overview of Inductor 172 and Inductor 372]

Overviews of the inductor 172 and the inductor 372 will be described referring to FIG. 3A and FIG. 3B. Configurations that are the same as or similar to those in FIG. 1 and FIG. 2 will be described as necessary.

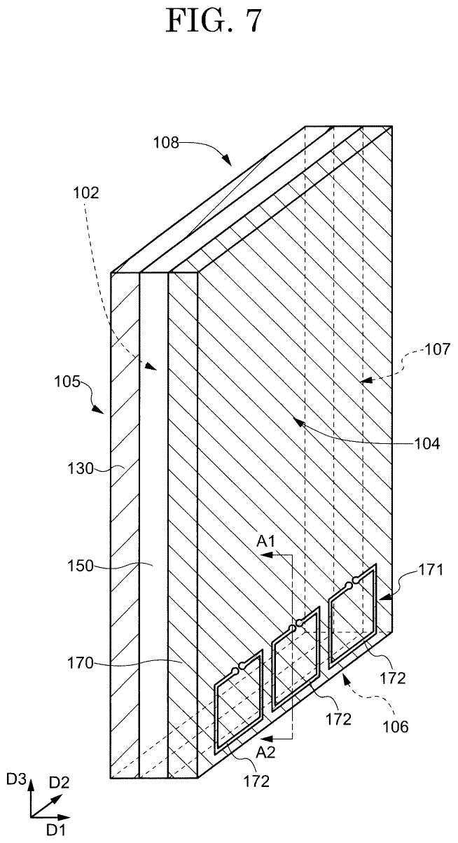

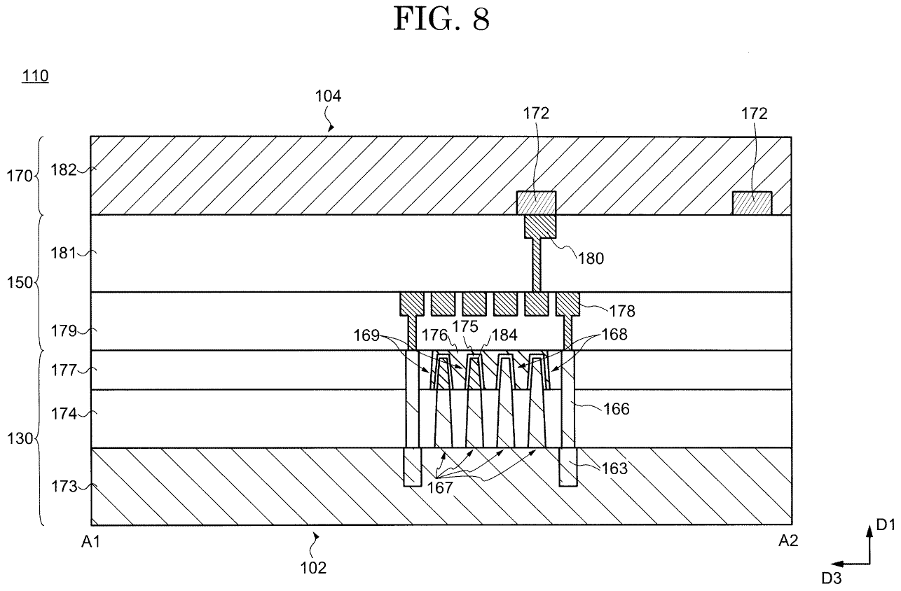

As described above, since the plurality of memory chips 110 has the same configuration, the configuration of the memory chip 110n+1 will be described here, and the configuration of the memory chip 110n will be described as needed. The memory chip 110n+1 includes an inductor layer 170 (for example, see FIG. 7 and FIG. 8). The inductor layer 170 includes a plurality of inductor groups 171, and each of the plurality of inductor groups 171 includes the plurality of inductors 172.

As shown in FIG. 3A or FIG. 3B, each of the plurality of inductors 172 is arranged in the direction D3 perpendicular to the direction D1 and the direction D2 (that is, the second surface 304).

As described above, the plurality of inductors 172 is arranged parallel to and spaced apart from the second side surface 146 and aligned in the direction D2. Each of the plurality of inductors 172 includes a terminal A, a terminal B, a first part 172a, a second part 172b, a third part 172c, a fourth part 172d, and a fifth part 172e. Although details will be described later, the inductor 172 is electrically connected to a transmission/reception circuit 114 (see FIG. 4) using the terminal A and the terminal B.

The fourth part 172d extends in the direction D2, one end of the fourth part 172d is electrically connected to the terminal A, and the other end of the fourth part 172d is electrically connected to one end of the fifth part 172e. The fifth part 172e extends in the direction D3 and the other end of the fifth part 172e is electrically connected to one end of the first part 172a. The first part 172a extends in the direction D2 and the other end of the first part 172a is electrically connected to one end of the second part 172b. The second part 172b extends in the direction D3 and the other end of the second part 172b is electrically connected to one end of the third part 172c. The third part 172c extends in the direction D2 and the other end of the third part 172c is electrically connected to the terminal B.

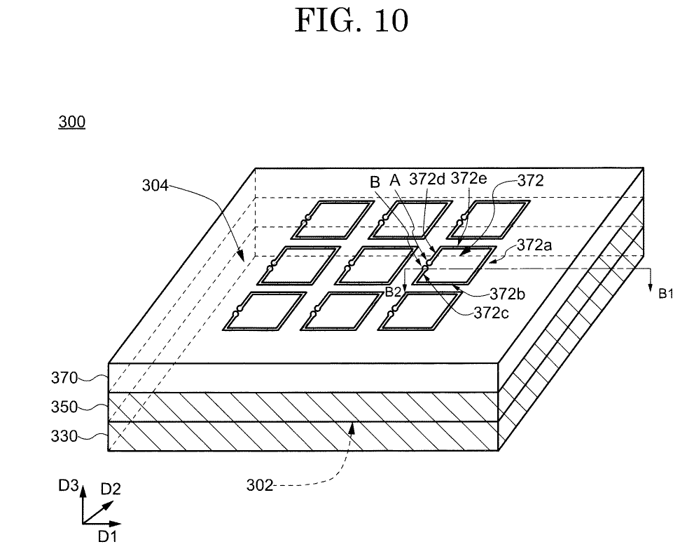

The TCI router chip 300 includes the inductor group 371 that includes the plurality of inductors 372 that are parallel to a position where the plurality of inductors 172 is arranged and that are arranged parallel to and proximate to the second surface 304. In addition, the TCI router chip 300 includes the inductor layer 370 (see, for example, FIG. 10 and FIG. 11), and the inductor layer 370 includes the plurality of inductors 372. The plurality of inductors 372 is arranged in a matrix along the direction D1 and the direction D2. Each of the plurality of inductors 372 includes a terminal C, a terminal D, a first part 372a, a second part 372b, a third part 372c, a fourth part 372d, and a fifth part 372e. Although details will be described later, the inductor 372 is electrically connected to a transmission/reception circuit 314 using the terminal C and the terminal D.

The fourth part 372d extends in the direction D2, one end of the fourth part 372d is electrically connected to the terminal C, and the other end of the fourth part 372d is electrically connected to one end of the fifth part 372e. The fifth part 372e extends in the direction D1 and the other end of the fifth part 372e is electrically connected to one end of the first part 372a. The first part 372a extends in the direction D2 and the other end of the first part 372a is electrically connected to one end of the second part 372b. The second part 372b extends in the direction D1 and the other end of the second part 372b is electrically connected to one end of the third part 372c. The third part 372c extends in the direction D2 and the other end of the third part 372c is electrically connected to the terminal D.

As shown in FIG. 3A and FIG. 3B, in the semiconductor module 10, the shape of the inductor 172 when a plane parallel to the direction D2 and the direction D3 is viewed from the direction D1, and the shape of the inductor 372 when a plane parallel to the direction D1 and the direction D2 is viewed from the direction D3 are, for example, quadrangular shapes. Since the memory chip 110 is standing perpendicular to the TCI router chip 300, the inductor 172 is arranged opposite to the inductor 372 by 90 degrees. Further, when a plane parallel to the direction D1 and the direction D2 is viewed from the direction D3, the first part 172a of the inductor 172 overlaps the first part 372a of the inductor 372. Among the plurality of inductors 172 and the plurality of inductors 372, one inductor 172 and one inductor 372 opposed to each other are magnetically coupled to each other, so that the inductors can communicate with each other in a one-to-one manner in a contactless manner. The communication between the inductors associated with the magnetic field coupling is called, for example, inductor communication, signal communication, data communication, or the like. In addition, the shape of the inductor 172 and the shape of the inductor 372 are not limited to a quadrangular shape. For example, the shape of the inductor 172 and the shape of the inductor 372 may be trapezoidal or pentagonal. The shape of the inductor 172 and the shape of the inductor 372 may be any shape capable of inductor communication.

As shown in FIG. 3B, for example, the inductor 172 and the inductor 372 are opposed to each other at 90 degrees, and can communicate one-to-one by magnetic field coupling. More specifically, effective inductor communication is performed by the first part 172a of the inductor 172 and the first part 372a of the inductor 372. The first part 172a mainly has a function of performing inductor communication with the first part 372a. In the inductor 172, the second part 172b, the third part 172c, the fourth part 172d, and the fifth part 172e excluding the first part 172a mainly have a function of supplying current to the first part 172a. Similar to the inductor 172, in the inductor 372, the second part 372b, the third part 372c, the fourth part 372d, and the fifth part 372e except for the first part 372a mainly have a function of supplying current to the first part 372a.

The inductor 372 has the same configuration and function as the inductor 172. In addition, in the semiconductor module 10, viewing a plane parallel to the direction D2 and the direction D3 from the direction D1 is referred to as a front view, and viewing a plane parallel to the direction D1 and the direction D2 from the direction D3 may be referred to as a plan view.

The semiconductor module 10 includes the memory cube 100 vertically placed on the TCI router chip 300, and a portion where the inductor 172 and the inductor 372 overlap is the first part 172a and the first part 372a, and the portion where the inductor 172 and the inductor 372 overlap is minimized. Further, the logic chip 200 does not include an inductor, and the inductor 172 in the memory cube 100 and the inductor 372 in the TCI router chip 300 are provided at positions apart from the logic chip 200. Therefore, the semiconductor module 10 can suppress generation of electromagnetic noise and the like of inductor communication associated with the logic chip 200, and can suppress malfunction associated with electromagnetic noise of the memory cube 100, the TCI router chip 300, and the logic chip 200.

### [1-1-3. Circuit Configuration of Semiconductor Module 10]

A schematic circuit configuration of the semiconductor module 10 will be described with reference to FIG. 4 and FIG. 5. As shown in FIG. 4, the memory cube 100 and the TCI router chip 300 are connected based on inductor communication. As shown in FIG. 4 or FIG. 5, the TCI router chip 300 and the logic chip 200 are electrically connected to each other by using a signal bus 340. In addition, each circuit in the memory cube 100, each circuit in the TCI router chip 300, and each circuit in the logic chip 200 may be electrically connected using the signal bus 340.

As shown in FIG. 4, the memory cube 100 includes a plurality of magnetic field coupled chip-to-chip interfaces (Through Chip Interface-IO (TCI-IO)) 112 and a plurality of memory modules 111. The plurality of TCI-IOs 112 is electrically connected to the memory module 111.

The TCI-IO 112 includes the inductor 172, the transmission/reception circuit 114, and a parallel-serial conversion circuit 113. The inductor 172 is electrically connected to the transmission/reception circuit 114 using the terminal A and the terminal B. The transmission/reception circuit 114 is electrically connected to the parallel-serial conversion circuit 113. The parallel-serial conversion circuit 113 is electrically connected to the memory module 111.

As described above, the inductor 172 has the function of performing inductor communication with the inductor 372 of the TCI router chip 300 in a contactless manner.

The transmission/reception circuit 114 has, for example, a function of amplifying a signal (data) received by the inductor 172 and a function of removing noise from the received signal (data). Further, the transmission/reception circuit 114 has a function of transmitting a desired signal (data) converted by using the parallel-serial conversion circuit 113 onto a radio wave, for example. The signal received by the inductor 172 includes a number of parallel signals from the TCI router chip 300. The desired signal includes a number of parallel signals from the memory module 111.

The parallel-serial conversion circuit 113 converts a large number of parallel signals from the TCI router chip 300 into serial signals (serial signal) by parallel-serial conversion in step 1, for example. The serial signal is transferred at high speed using one signal path (wiring). In step 2, the parallel-serial conversion circuit 113 performs serial-parallel conversion on the serial signal immediately before the memory module 111, returns the serial signal to a plurality of parallel signals, and then transmits the plurality of parallel signals to the memory module 111. In the case where the memory module 111 transmits a signal (data) to the TCI router chip 300, the parallel-serial conversion circuit 113 performs step 1 following step 2, for example. The parallel-serial conversion circuit 113 is called, for example, a SerDes circuit (Serialize and Deserialize Circuit).

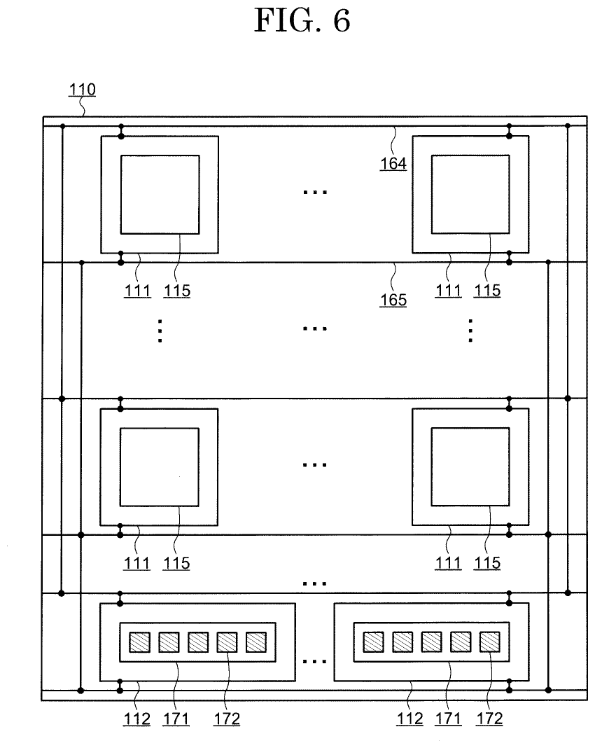

The memory module 111 includes, for example, a function of generating the plurality of parallel signals to be transmitted and a function of controlling the plurality of received parallel signals and storing them in a memory cell array 115 (see FIG. 6).

As shown in FIG. 4 or FIG. 5, the TCI router chip 300 includes, for example, a plurality of TCI-IOs 312, a plurality of network routers (Router(R)) 318, a plurality of external IOs 316, and a plurality of memory controllers 319.

The TCI-IO 312, the external IO 316, and the memory controller 319 are functional blocks that constitute an LSI (Large Scale Integration (large scale integrated circuit)). The functional blocks constituting the LSI are called, for example, IP (Intellectual Property) cores, IP, macros, or the like. The IP cores include a CPU (Central Processing Unit), a GPU (Graphics Processing Unit), memories, or the like.

The IP cores, such as the plurality of TCI-IOs 312, the plurality of external IOs 316, and the plurality of memory controllers 319, include a network interface (Network Interface (NI)) 317.

In addition, the IP cores such as the plurality of TCI-IOs 312, the plurality of external IOs 316, and the plurality of memory controllers 319 may not include the NI 317, and the NI 317 may be located outside the plurality of TCI-IOs 312, the plurality of external IOs 316, and the plurality of memory controllers 319, and each of the plurality of TCI-IOs 312, the plurality of external IOs 316, and the plurality of memory controllers 319 may be electrically connected to the R 318 corresponding to each circuit via the NI 317.

The IP cores, such as the plurality of TCI-IOs 312, the plurality of external IOs 316, and the plurality of memory controllers 319, are electrically connected to the R 318 corresponding to the NI 317 of the respective IP core. Therefore, the IP cores such as the plurality of TCI-IOs 312, the plurality of external IOs 316, and the plurality of memory controllers 319 are connected in a network form using a plurality of Rs 318. The plurality of Rs 318 is electrically connected using, for example, a plurality of signal buses 340.

A network configuration of the IP core using the plurality of Rs 318 may be mesh-like as shown in FIG. 5. The network configuration of the IP core shown in FIG. 5 is an example, and the network configuration of the IP core is not limited to the configuration shown in FIG. 5. The network configuration of the IP core is appropriately selected depending on the specifications and applications of the semiconductor module 10, the number of the IP cores included in the semiconductor module 10, and the like.

The plurality of TCI-IOs 312 includes, for example, TCI-IOs 312a, 312b, . . . , and 312e. If each of the plurality of TCI-IOs 312 is indistinguishable, the TCI-IO is expressed as the TCI-IO 312. If each of the plurality of TCI-IOs 312 is distinguished, the plurality of TCI-IO are expressed as the TCI-IO 312a, 312b. . . . , 312e and the like. In addition, the number of the plurality of TCI-IOs 312 included in the semiconductor module 10 is not limited, and is appropriately selected depending on the specifications and applications of the semiconductor module 10, the number of the IP cores included in the semiconductor module 10, and the like.

The TCI-IO 312 includes the inductor 372, the transmission/reception circuit 314, a parallel-serial conversion circuit 313, and the NI 317. The inductor 372 is electrically connected to the transmission/reception circuit 314 using the terminal C and the terminal D. The transmission/reception circuit 314 is electrically connected to the parallel-serial conversion circuit 313. The parallel-serial converter 313 is electrically connected to the NI 317. The TCI-IO 312 (NI 317) is electrically connected to the R 318.

The configurations and functions of the inductor 372, the transmission/reception circuit 314, the parallel-serial conversion circuit 313, and the memory controller 319 are the same as those of the inductor 172, the transmission/reception circuit 114, the parallel-serial conversion circuit 113, and the memory module 111. Therefore, the configurations and functions of the inductor 372, the transmission/reception circuit 314, the parallel-serial conversion circuit 313, and the memory controller 319 will not be described here.

For example, the NI 317 can convert data transmitted and received using the signal bus 340 into a data format corresponding to the IP core electrically connected to the NI 317, and can convert a data format corresponding to the IP core into a data format corresponding to the signal bus 340. As a result, since the semiconductor module 10 can transmit and receive both an address and the data using the signal bus 340, a bus width can be made smaller than that of the module including the signal bus arranged in a concentrated manner. In addition, since the semiconductor module 10 can transmit and receive data without depending on the data format corresponding to the respective IP cores, the number of the signal buses 340 can be suppressed from increasing.

Here, the data transmitted and received using the signal bus 340 includes, for example, addresses that can identify IP cores electrically connected to the NI 317.

The plurality of Rs 318 includes, for example, Rs 318a, 318b, . . . , and 318i. As in the TCI-IO, in the case where each of the plurality of Rs 318 is not distinguished, the plurality of Rs is expressed as R 318. In the case where each of the plurality of Rs 318 is distinguished, the plurality of Rs is expressed as the Rs 318a, 318b, . . . , and 318i, and the like. The number of the plurality of Rs 318 included in the semiconductor module 10 is not limited, and is appropriately selected depending on the specifications and applications of the semiconductor module 10, the number of the IP cores included in the semiconductor module 10, and the like.

Each of the plurality of Rs 318 is electrically connected to the IP core and signal bus 340. Each of the plurality of Rs 318 includes a plurality of switches, and can control a transmission/reception path of the data to/from the respective IP cores connected in a network form based on the addresses. As a result, the semiconductor module 10 can transmit and receive data to and from the desired IP cores among the IP cores connected in the network form by controlling the plurality of switches of the plurality of Rs 318. Further, the semiconductor module 10 can change the arrangement and address of the R 318 without depending on the arrangement of the IP core in accordance with the control of the transmission and reception path of the data to and from the IP core using the R 318, so that the transmission and reception path of the data can be flexibly set.

Further, the R 318 can also function as a repeater (also referred to as a bus buffer) that aggregates a plurality of signal buses 340 and divides the routed signal buses 340 appropriately. Therefore, the semiconductor module 10 can suppress concentration of the plurality of signal buses 340. As a consequence, for example, flexibility of the position of the R 318 can be improved, and constraint of the arrangement of the IP cores connected to the R 318 can be relaxed.

The external IO 316 includes, for example, the NI 317. The external IO 316 is electrically connected to the R 318 via the NI 317. The external IO 316 is electrically connected to the logic chip 200, the memory cube 100, and an external circuit (not shown, for example, a power supply circuit) via the R 318, and has a function of transmitting and receiving signals between the external circuit and the logic chip 200 and the memory cube 100.

The memory controller 319 includes, for example, the NI 317. For example, the memory controller 319 is electrically connected to the R 318 via the NI 317. The memory controller 319 is electrically connected to the logic chip 200 and the memory cube 100 via the R 318, and has a function of transmitting and receiving signals between the memory cube 100 and the logic chip 200.

As shown in FIG. 5, the logic chip 200 includes, for example, a plurality of CPUs (a Central Processing Unit 211, a memory interface 212, a PCIe interface (PCI Express Interface (PCIeIF)) 213, an Ethernet interface (Ethernet Interface (EIF)) 214, and a plurality of Rs 218.

The plurality of CPUs 211, the memory interface 212, the PCIeIF 213, and the EIF 214 may be IP cores. Each of the plurality of CPUs 211, the memory interface 212, the PCIeIF 213, and the EIF 214 includes a NI 217.

In addition, each of the plurality of CPUs 211, the memory interface 212, the PCIeIF 213, and the EIF 214 may not include the NI 217, and the NI 217 may be located outside the plurality of CPUs 211, the memory interface 212, the PCIeIF 213, and the EIF 214, and each of the plurality of CPUs 211, the memory interface 212, the PCIeIF 213, and the EIF 214 may be electrically connected to the R 318 corresponding to the respective circuitry via the NI 217. Configurations and functions of the NI 217 are the same as the configurations and functions of the NI 317. Therefore, the configuration and function of the NI 217 will be omitted here.

The IP cores, such as the plurality of CPUs 211, memory interface 212, the PCIeIF 213, and the EIF 214, are electrically connected to the R 218 corresponding to the NI 217 of the respective IP core. Therefore, the IP cores, such as the plurality of CPUs 211, the memory interface 212, the PCIeIF 213, and the EIF 214, are connected in a network form using the plurality of Rs 218. The plurality of Rs 218 is electrically connected using, for example, the plurality of signal buses 340. Configurations and functions of the plurality of R 218 is the same as the configurations and functions of the plurality of Rs 318. Therefore, the configurations and functions of the plurality of Rs 218 will be omitted here.

The plurality of CPUs 211 includes, for example, CPUs 211a, 211b, and 211c. If each of the plurality of CPUs 211 is not distinguished, the CPUs are expressed as the CPU 211. If each of the plurality of CPUs 211 is distinguished, the plurality of CPUs is expressed as the CPUs 211a, 211b, and 211c. The number of the plurality of CPUs 211 included in the semiconductor module 10 is not limited, and is appropriately selected depending on the specifications and applications of the semiconductor module 10.

The plurality of Rs 218 includes, for example, Rs 218a, 218b, . . . , and 218f. Similar to the plurality of Rs 318, if each of the plurality of Rs 218 is not distinguished, the plurality of Rs is represented as the R 218. If each of the plurality of Rs 218 is distinguished, the plurality of Rs is expressed as the Rs 218a, 218b, . . . , and 218f, and the like. The number of the plurality of Rs 218 included in the semiconductor module 10 is not limited, and is appropriately selected depending on the specifications and applications of the semiconductor module 10.

Here, the data transmitted and received using the signal bus 340 includes, for example, addresses that can identify the IP cores electrically connected to the NI 217.

Each of the plurality of CPUs 211 is a logical module including a so-called arithmetic circuit. Each of the plurality of CPUs 211 has a function of controlling transmission of signals (data) to the memory cube 100, the TCI router chip 300, the memory interface 212, the PCIeIF 213, the EIF 214, and the plurality of Rs 218, or reception of signals (data) from the memory cube 100, the TCI router chip 300, the memory interface 212, the PCIeIF 213, the EIF 214, and the plurality of Rs 218. For example, the CPU 211 transmits a signal for driving the memory module 111 via the TCI router chip 300.

The memory interface 212 is, for example, a DRAM interface (Dynamic Random Access Memory (DRAM) IO), and has a function of transmitting and receiving signals between a DRAM (not shown) and the logic chip 200.

The PCIeIF 213 is, for example, an interface that complies with the serial bus standard used for connecting an expansion card or the like in a computer. The PCIeIF 213 has a function of transferring data at high speed to, for example, a CPU, a memory, a storage, or the like connected to the expansion card mounted on a computer.

The EIF 214 is, for example, an interface having a function of connecting a network medium (cable) to the semiconductor module 10 and all devices (computers, printers, or the like) communicating via the network.

As described above, each circuit in the TCI router chip 300 and each circuit in the logic chip 200 are connected in a network form via the network router (Router (R)), and each circuit in the memory cube 100 and each circuit in the TCI router chip 300 and each circuit in the logic chip 200 are connected using inductor communication. The semiconductor module 10 is a so-called network-on-chip (Network on Chip (NoC)) in which the plurality of IP cores are connected in the network form, and is a module capable of communicating using the NoC and the inductor communication.

For example, as shown in FIG. 5, the R 318h connected to the memory controller 319 is connected to the R 318g, the R 318e and the R 318i in the TCI router chip 300, and the R 218b in the logic chip 200. That is, the memory controller 319 connected to the R 318h is electrically connected to the memory controller 319 connected to the R 318g, the TCI-IO 312e connected to the R 318e, and the external IO 316 connected to the R 318i, and is electrically connected to the PCIeIF 213 connected to the R 218b in the logic chip 200 via the signal bus 340. The TCI-IO 312e communicates with the inductor 172 in the memory cube 100 using the inductor 372 and is electrically connected to the memory module 111.

Further, the R 218b connected to the PCIeIF 213 is connected to the R 218a, the R 218c and the R 218e in the logic chip 200. That is, the PCIeIF 213 connected to the R 218b is electrically connected to the memory interface 212 connected to the R 218a, the EIF 214 connected to the R 218c, and the CPU 211b connected to the R 218e.

Thus, the CPU 211b transmits a signal for driving the memory module 111 to the TCI-IO 312e via the R 218e, the R 218b, the signal bus 340, the R 318h, and the R 318e, and the TCI-IO 312e communicates with the inductor 172 in the memory cube 100 using the inductor 372, and transmits a signal for driving the memory module 111 to the memory module 111.

The semiconductor module 10 electrically connects the TCI router chip 300 and the logic chip 200 using a router connected in a network shape, and is capable of communication using a network type bus, and is capable of contactless communication using inductor communication with the TCI router chip 300 and the memory cube 100 vertically placed on the TCI router chip 300. Therefore, the semiconductor module 10 is a module that is three-dimensionally connected using a connection based on an electric connection and contactless communication, and can reduce power consumption by suppressing a signal delay associated with wirings in a horizontal direction parallel to the direction D1 and the direction D2 and a vertical direction (direction D3).

### [1-2. Overview of Memory Cube 100]

Next, an overview of the memory cube 100 will be described referring to FIG. 1, FIG. 3A, and FIG. 6 to FIG. 8. FIG. 6 is a schematic diagram showing the configuration of the memory chip 110. FIG. 7 is a perspective view showing the configuration of the memory chip 110. FIG. 8 is a schematic cross-sectional view of the memory chip 110 taken along a line A1-A2 shown in FIG. 7. Configurations that are the same as or similar to those in FIG. 1 to FIG. 5 will be described as necessary.

Referring to FIG. 1, as described in “1-1. Overview of Semiconductor Module 10”, the memory cube 100 includes a configuration in which the plurality of memory chips 110 are stacked in the direction D1. The second side surface 146 is positioned so as to be in contact with the adhesive layer 400 and face the second surface 304 of the TCI router chip 300, and the memory cube 100 is arranged on the second surface 304 of the TCI router chip 300.

As shown in FIG. 6, the memory chip 110 includes the plurality of memory modules 111, the plurality of TCI-IOs 112, a power supply wiring 164, and a grounding wiring 165. Each of the plurality of memory modules 111 includes the memory cell array 115. Each of the plurality of TCI-IOs 112 includes the plurality of inductor groups 171, and the inductor group 171 includes a plurality of inductors 172. The memory chip 110 shown in FIG. 6 is, for example, a SRAM (Static Random Access Memory) chip.

The memory module 111 has a function of controlling the storage of a signal (data) to the memory cell array 115, reading of a signal (data) from the memory cell array 115, transmission of a signal (data) to the TCI-IO 112, and reception of a signal (data) from the TCI-IO 112, and the like.

The memory cell array 115 includes a plurality of memory cells (not shown). Each of a plurality of memory cell arrays 115 is, for example, a SRAM, and each of the plurality of memory cells is a SRAM cell. The SRAM, the SRAM cell, and the memory module 111 for SRAM may employ a technique used in the technical field of SRAM. Therefore, the detailed description will be omitted here. In addition, the plurality of memory cell arrays 115 and the plurality of memory cells may be memory cell arrays and memory cells other than SRAM, and may be, for example, DRAM (Dynamic Random Access Memory) and DRAM cells, MRAM (Magnetoresistive Random Access Memory) and MRAM cells, or the like.

The plurality of memory modules 111 and the plurality of TCI-IOs 112 are electrically connected to the power supply wiring 164 and the grounding wiring 165. The power supply wiring 164 and the grounding wiring 165 are electrically connected to an external circuit (not shown), for example, and are supplied with a power supply voltage VDD, a voltage VSS, and the like. The power supply VDD is, for example, 1 V, 3 V, or the like. The voltage VSS is, for example, a grounding voltage, 0 V, or the like.

As shown in FIG. 1 and FIG. 7, each of the plurality of memory chips 110 includes, for example, a transistor layer 130, a wiring layer 150, and the inductor layer 170. The plurality of memory chips 110 includes, for example, the memory chip 110n (see FIG. 3A) and the memory chip 110n+1 (see FIG. 3A) that is adjacent to the memory chip 110n.

As shown in FIG. 7, the memory chip 110 includes a first surface 102 that is parallel to the direction D2 and the direction D3, and a second surface 104 that is opposed to the first surface 102 with respect to the direction D1. The first surface 102 is an exposed surface of the transistor layer 130. The second surface 104 is an exposed surface of the inductor layer 170. The first surface 102 and the second surface 104 are parallel to the first surface 142 and the second surface 144.

The memory chip 110 also includes a first side surface 105 perpendicular to the first side surface 102 and the second side surface 104, a second side surface 106 adjacent to the first side surface 105, a third side surface 107 adjacent to the second side surface 106, and a fourth side surface 108 adjacent to the third side surface 107 and the first side surface 105. The first side surface 105 is part of the first side surface 145, the second side surface 106 is part of the second side surface 146, the third side surface 107 is part of the third side surface 147, and the fourth side surface 108 is part of the fourth side surface 148.

In addition, a portion of the power supply wiring 164 and a portion of the ground wiring 165 are exposed to, for example, the first side surface 105, the fourth side surface 108, or the third side surface 107, and are electrically connected to a side surface wiring electrically connected to the external circuit. The power supply voltage VDD and the voltage VSS are supplied to a portion of the power supply wiring 164 and the portion of the grounding wiring 165 through the external circuit and the side surface wiring. The side surface wiring can be formed by employing a technique used in the technical field of the semiconductor module.

The inductor layer 170 includes the plurality of inductor groups 171. Each of the plurality of inductor groups 171 includes the plurality of inductors 172. The plurality of inductor groups 171 are arranged parallel to the direction D2 and the direction D3 (that is, the first surface 102 and the second surface 104) and perpendicular to the direction D1 and the direction D2. Each of the plurality of inductor groups 171 is arranged away from the fourth side surface 108, proximate to the second side surface 146, and is arranged to extend in the direction D2. Although the number of inductors 172 shown in FIG. 7 is three, the number of inductors 172 shown in FIG. 7 is an example. The number of inductors 172 can be appropriately changed according to the specifications, applications, and the like of the semiconductor module 10.

As shown in FIG. 3A or FIG. 7, the plurality of inductor groups 171 are adjacent to the second side surface 106 of the memory chip 110 and are parallel to the direction D2. Each of the plurality of inductor groups 171 includes the plurality of inductors 172. The plurality of inductors 172 includes, for example, an inductor having a function of data communication (data transmission) and an inductor having a function of clock communication (clock transmission). Each inductor 172 may perform inductor communication with a corresponding inductor 372 on a one-to-one basis in response to a clock received by clock communication (synchronously), and each inductor 172 may perform inductor communication with a corresponding inductor 372 on the one-to-one basis without synchronizing (asynchronously) with a clock received by clock communication. Further, for example, each inductor 172 may perform inductor communication with the corresponding inductor 372 in the one-to-one manner asynchronously with clock communication.

As shown in FIG. 8, the transistor layer 130 includes, for example, a substrate 173, a wiring 163, an insulating layer 174, fins 167, a wiring 166, an activation region 184, a gate insulating film 175, a gate electrode 176, an N-type transistor 168, a P-type transistor 169, and an insulating layer 177. The substrate 173 is, for example, an N-type Si substrate or an N-type Si-wafer. As an example, the memory chip 110 is formed by a 2 nm using CMOS processes, and is formed using a fin-type transistor as shown in FIG. 8, but may be formed using a CMOS process other than 2 nm, or may be formed using a transistor other than a fin-type transistor. A structure of the transistor of the memory chip 110 may be appropriately selected according to the specifications, applications, and the like of the semiconductor module 10.

The wiring layer 150 includes a multilayer wiring structure in which wirings and insulating layers are alternately stacked. The wiring layer 150 includes, for example, a wiring 178, an insulating layer 179, a wiring 180, and an insulating layer 181. The number of layers of the multilayer wiring in the wiring layer 150 is not limited to the two layers shown in FIG. 8. The number of layers of the multilayer wiring in the wiring layer 150 may be three or more. The number of layers of the multilayer wiring in the wiring layer 150 can be appropriately changed according to the specifications, applications, and the like of the semiconductor module 10.

The inductor layer 170 includes, for example, an insulating layer 182 and the plurality of inductors 172. The inductor layer 170 includes the plurality of inductor groups 171.

The wiring 163 is a so-called buried electrode. The wiring 178 and the wiring 166 are, for example, connected to an external circuit via the side surface wiring described above and the signal (data), the power supply voltage VDD, the voltage VSS, and the like are supplied to the wiring 163 via the side surface wiring, the wiring 178, and the wiring 166. The wiring 178 and the wiring 180 have, for example, a damascene structure, and the wiring 166 has, for example, a structure corresponding to a through electrode.

The inductor 172 is connected to the wiring 180, and the wiring 180 is connected to the wiring 178. Although not shown, the wiring 178 is electrically connected to a source electrode or a drain electrode of the N-type transistor 168, a source electrode or a drain electrode of the P-type transistor 169, the gate electrode 176, and the like. The signal (data) received by the inductor 172 is transmitted to the N-type transistor 168, the P-type transistor 169, and the like via the wiring 180 and the wiring 178. The signal (data) including a result calculated by logical operation is transmitted to the inductor 172 via the N-type transistor 168, the P-type transistor 169, the wiring 180, and the wiring 178.

### [1-3. Overview of TCI Router Chip 300]

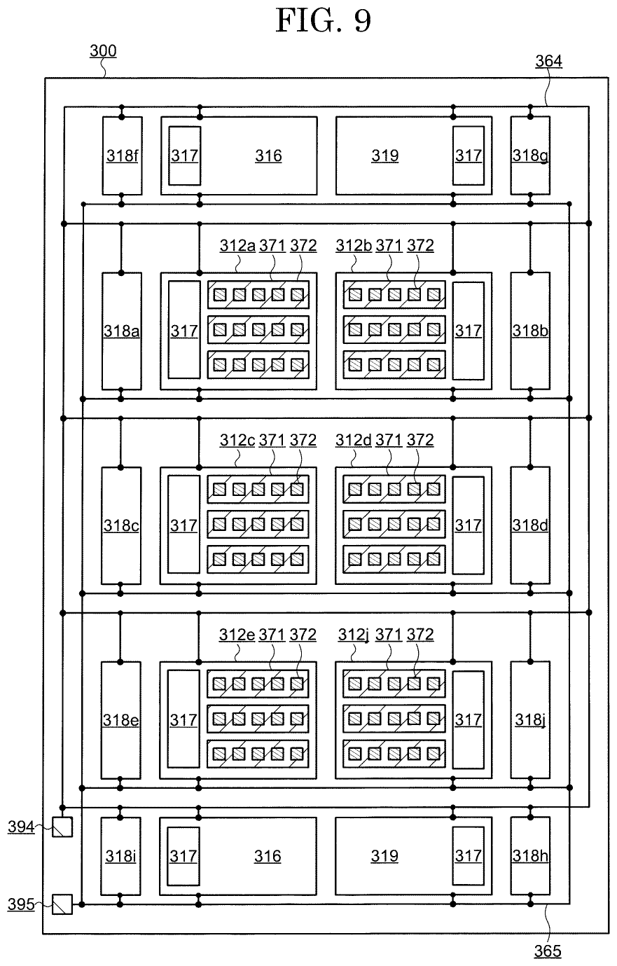

Next, an overview of the TCI router chip 300 will be described referring to FIG. 1, FIG. 3A, and FIG. 9 to FIG. 11. FIG. 9 is a diagram showing a configuration of the TCI router chip 300. FIG. 10 is a perspective view showing a configuration of the TCI router chip 300. FIG. 11 is a cross-sectional view schematically showing a cross-sectional configuration of the TCI router chip 300 along a line B1-B2 shown in FIG. 10. The same or similar configurations as those in FIG. 1 to FIG. 8 will be described as necessary.

Referring to FIG. 1, as described in “1-1. Overview of Semiconductor Module 10”, the TCI router chip 300 includes a configuration in which the transistor layer 330, the wiring layer 350, and the inductor layer 370 are stacked in this order in the direction D3, and includes the first surface 302 parallel to the direction D1 and the direction D2, and the second surface 304 opposite to the first surface 302. The first surface 302 is an exposed surface of the transistor layer 330. The second surface 304 is an exposed surface of the inductor layer 370.

As shown in FIG. 1 and FIG. 10, the inductor layer 370 includes a plurality of inductor groups 371. The plurality of inductor groups 371 (for example, see FIG. 3A) includes a plurality of inductors 372. The plurality of inductors 372 is arranged in a matrix parallel to the directions D1 and D2 (that is, the first surface 302 and the second surface 304).

As shown in FIG. 11, the transistor layer 330 includes, for example, the substrate 373, a wiring 363, the through electrode 360, the through electrode 394, a through electrode 395, an insulating layer 374, a fin 367, a wiring 366, an activation region 384, a gate insulating film 375, a gate electrode 376, the N-type transistor 368, the P-type transistor 369, and an insulating layer 377. The wiring layer 350 includes a multilayer wiring structure in which wirings and insulating layers are alternately stacked. The wiring layer 350 includes, for example, a wiring 378, an insulating layer 379, a wiring 380, and an insulating layer 381. The inductor layer 370 includes, for example, an insulating layer 382 and the plurality of inductors 372.

The configuration and the function of each of the substrate 373, the wiring 363, the insulating layer 374, the fin 367, the wiring 366, the activation region 384, the gate insulating film 375, the gate electrode 376, the N-type transistor 368, the P-type transistor 369, the insulating layer 377, the wiring 378, the insulating layer 379, the wiring 380, the insulating layer 381, the insulating layer 382, and the inductor 372 is same as the configuration and the function of each of the substrate 173, the wiring 163, the insulating layer 174, the fin 167, the wiring 166, the activation region 184, the gate insulating film 175, the gate electrode 176, the N-type transistor 168, the P-type transistor 169, the insulating layer 177, the wiring 178, the insulating layer 179, the wiring 180, the insulating layer 181, the insulating layer 182, and the inductor 172 described in “1-2. Overview of Memory Cube 100”. Therefore, each layer and wiring constituting the transistor layer 330, the wiring layer 350, and the inductor layer 370 will be described as necessary.

The through electrode 360, the through electrode 394, and the through electrode 395 are electrically connected to the wiring 363 that is a so-called buried wiring, and a portion of the through electrode 360, a portion of the through electrode 394, and a portion of the through electrode 395 are exposed to the first surface 302. A portion of the through electrode 360, a portion of the through electrode 394, and a portion of the through electrode 395 are electrically connected to the wiring 280 exposed on the second surface 204 of the logic chip 200. The signal (data), the power supply voltage VDD, the voltage VSS, and the like are supplied from the external circuit to the through electrode 360, the through electrode 394, and the through electrode 395 via the logic chip 200 (for example, the wire 280).

Referring to FIG. 4 and FIG. 5, as described in “1-1-3. Circuit Configuration of Semiconductor Module 10”, as shown in FIG. 9, the TCI router chip 300 includes, for example, the plurality of TCI-IOs 312, the plurality of Rs 318, the plurality of external IOs 316, and the plurality of memory controllers 319. In addition, the plurality of TCI-IOs 312 includes the TCI-IOs 312a to 312e and a TCI-IO 312j, and the plurality of Rs 318 includes the R 318a to a R 318j. Each of the plurality of TCI-IOs 312 includes a plurality of inductor groups 271, and the inductor group 271 includes a plurality of inductors 372. In addition, the configuration of the TCI router chip 300 shown in FIG. 9 is an example, and the configuration of the TCI router chip 300 is not limited to the example shown in FIG. 9. For example, the TCI router chip 300 may include IP cores other than those shown in FIG. 9.

A power supply wiring 364 is electrically connected to the through electrode 394, a ground wiring 365 is electrically connected to the through electrode 395, and the signal bus 340 (see FIG. 4) is electrically connected to the through electrode 360 (see FIG. 11). As shown in FIG. 9, the TCI router chip 300 includes one through electrode 394 and one through electrode 395, and includes one system of power supply wiring 364 and one system of grounding wiring 365. Further, as shown in FIG. 11 or FIG. 5, the TCI router chip 300 includes two through electrodes 360 as one example and includes three systems of signal buses 340. The number of the through electrodes 394, the through electrodes 395, and the through electrodes 360 included in the TCI router chip 300 and the number of the power supply wirings 364, the grounding wirings 365, and the signal buses 340 are not limited to those shown in FIG. 11 or FIG. 5. The TCI router chip 300 may include two or more through electrodes 394, through electrodes 395, and through electrodes 360, and may include two or more power supply wirings 364, grounding wirings 365, and signal buses 340. The number of the through electrodes 394, the through electrodes 395, and the through electrodes 360 included in the TCI router chip 300 and the number of systems of the power supply wirings 364, the grounding wirings 365, and the signal buses 340 can be changed as appropriate depending on the specifications, applications, and the like of the semiconductor module 10.

As described in “1-1. Overview of Semiconductor Module 10”, in the TCI router chip 300, the second surface 304 is mounted on the adhesive layer 400, and the first surface 302 is mounted on the second surface 204 of the logic chip 200. That is, the TCI router chip 300 is face-up mounted to the adhesive layer 400. As a result, the plurality of inductors 372 arranged on the second surface 304 side are located away from the logic chip 200. Therefore, it is possible to suppress generation of electromagnetic noise and the like in inductor communication associated with the logic chip 200.

As shown in FIG. 3A or FIG. 10, the plurality of inductors 372 is arranged in a matrix in the direction D1 and the direction D2 on the second surface 304 side. Similar to the plurality of inductors 172, the plurality of inductors 372 includes, for example, an inductor having a function of data communication (data transmission) and an inductor having a function of clock communication (clock transmission). Similar to each inductor 172, each inductor 372 may perform inductor communication with the corresponding inductor 172 on a one-to-one basis depending on the clock received by clock communication (synchronously), and may perform inductor communication with the corresponding inductor 172 on a one-to-one basis without synchronizing (asynchronously) with the clock received by clock communication.

### [1-4. Overview of Logic Chip 200]

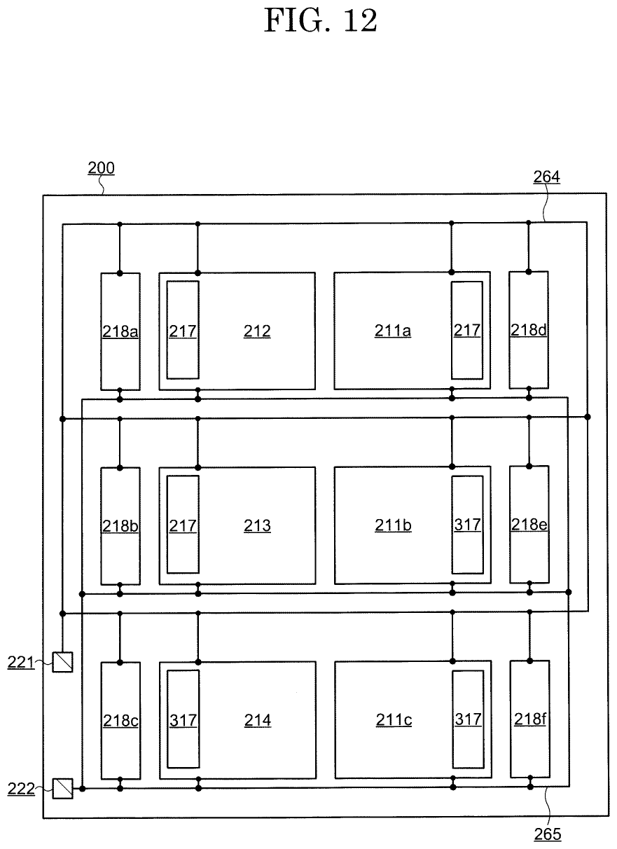

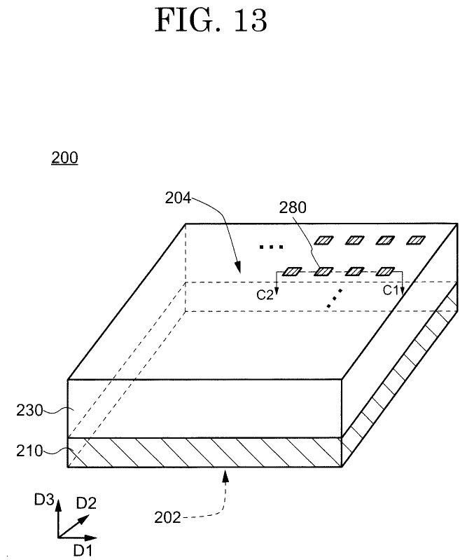

Next, an overview of the logic chip 200 will be described with reference to FIG. 1 and FIG. 12 to FIG. 14. FIG. 12 is a block diagram showing a configuration of the logic chip 200. FIG. 13 is a perspective view showing the configuration of the logic chip 200. FIG. 14 is a cross-sectional view schematically showing a cross-sectional configuration of the logic chip 200 along a line C1-C2 shown in FIG. 13. Configurations that are the same as or similar to those in FIG. 1 to FIG. 11 will be described as necessary.

Referring to FIG. 1, as described in “1-1. Overview of Semiconductor Module 10”, the logic chip 200 includes a configuration in which the lower wiring layer 210 and the transistor layer 230 are stacked in the direction D3 in this order as shown in FIG. 13, and includes the first surface 202 parallel to the direction D1 and the direction D2, and the second surface 204 opposite the first surface 202. The first surface 202 is an exposed surface of the lower wiring layer 210. The second surface 204 is an exposed surface of the transistor layer 230.

As shown in FIG. 14, the transistor layer 230 includes, for example, the substrate 273, a wiring 263, the through electrode 260, a through electrode 294, a through electrode 295, an insulating layer 274, a fin 267, a wiring 266, an activation region 284, a gate insulating film 275, a gate electrode 276, the N-type transistor 268, the P-type transistor 269, and an insulating layer 277. The transistor layer 230 includes a multilayer wiring structure in which wirings and insulating layers are alternately stacked. The multilayer wiring structure includes, for example, a wiring 278, an insulating layer 279, the wiring 280, and an insulating layer 281.

The configuration and the function of each of the substrate 273, the wiring 263, the through electrode 260, the through electrode 294, the through electrode 295, the through electrode 274, the fin 267, the wiring 266, the activation region 284, the gate insulating film 275, the gate electrode 276, the N-type transistor 268, the P-type transistor 269, the insulating layer 277, the wiring 278, the insulating layer 279, the wiring 280, and the insulating layer 281 is same as the configuration and the function of each of the substrate 373, the wiring 363, the through electrode 360, the through electrode 394, the through electrode 395, the insulating layer 374, the fin 367, the wiring 366, the activation region 384, the gate insulating film 375, the gate electrode 376, the N-type transistor 368, the P-type transistor 369, the insulating layer 377, the wiring 378, the insulating layer 379, the wiring 380, the insulating layer 381, and the insulating layer 382 described in “1-3. Overview of TCI Router Chip 300”. Therefore, each layer and wiring constituting the transistor layer 230 will be described as necessary.

The lower wiring layer 210 includes a multilayer wiring structure in which wirings and insulating layers are alternately stacked. The lower wiring layer 210 includes, for example, the electrode pad 220, the electrode pad 221, the electrode pad 222, an insulating layer 223, a through electrode 224, a through electrode 225, a through electrode 226, an insulating layer 227, the wiring 228, and an insulating layer 229. The number of layers of the multilayer wiring in the lower wiring layer 210 is not limited to the two layers shown in FIG. 14. The number of layers of the multilayer wiring in the lower wiring layer 210 may be three or more. The number of layers of the multilayer wiring in the lower wiring layer 210 can be appropriately changed according to the specifications, applications, and the like of the semiconductor module 10.

The lower wiring layer 210 is a wiring layer for so-called back side power delivery (Backside Power Delivery(BPD)). The BPD is a technique used in the technical field of semiconductor modules, and detailed explanation is omitted here. Briefly, for example, BPD is a technique for separating the supply of a signal (data), a power supply voltage, a voltage, and the like on the second surface 204 side and the first surface 202 side of the substrate 273, respectively. For example, the use of the BPD enables scaling of metal wiring connections inside the semiconductor module 10, simplifies complex metal wiring patterning, and reduces manufacturing costs of the semiconductor module 10.

The through electrode 260, the through electrode 294, and the through electrode 295 are electrically connected to the wiring 263 that is a so-called buried wiring. The through electrode 260, the through electrode 294, and the through electrode 295 are electrically connected to, for example, the second layer wiring 228 counted from the first surface 202 side. The second layer wiring 228 is electrically connected to the electrode pad 222 using, for example, a plurality of through electrodes 226. Further, the second layer wiring 228 is electrically connected to the electrode pad 221 using, for example, a plurality of through electrodes 225, and is electrically connected to the electrode pad 220 using a plurality of through electrodes 224. For example, the power supply voltage VDD is supplied from the external circuit to the electrode pad 221, the voltage VSS is supplied from the external circuit to the electrode pad 222, and the signal (data) is supplied from the external circuit to the electrode pad 220. In this way, the signal (data), the power supply voltage VDD, the voltage VSS, and the like are supplied from the external circuit to the through electrode 226, the through electrode 225, and the through electrode 224 via the electrode pad, and are supplied to the inside of the logic chip 200. The electrode pad 220, the electrode pad 221, and the electrode pad 222 are wirings of the first layer counted from the first surface 202 side.

Referring to FIG. 4 and FIG. 5, as described in “1-1-3. Circuit Configuration of Semiconductor Module 10”, as shown in FIG. 12, the logic chip 200 includes, for example, the plurality of CPUs 211, the memory interface 212, the PCIeIF 213, the EIF 214, and the plurality of Rs 218. The plurality of CPUs 211 includes the CPUs 211a to 211c, and the plurality of Rs 218 includes the Rs 218a to R318f. In addition, the configuration of the logic chip 200 shown in FIG. 12 is an example, and the configuration of the logic chip 200 is not limited to the example shown in FIG. 12. For example, the logic chip 200 may include IP cores other than those shown in FIG. 12.

The CPU 211 has a function of controlling transmission of a signal (data) to the TCI-IO 312, and reception of a signal (data) from the TCI-IO 312, and the like. The CPU 211 has a function of driving the memory module 111 in the memory chip 110. For example, the CPU 211 transmits a signal for driving the memory module 111 via the TCI-IO 312. The CPU 211 is a logic module and may include arithmetic circuits such as, for example, the CPU (Central Processing Unit).

For example, the power supply wiring 264 is electrically connected to the electrode pad 221 via the through electrode 294, the wiring 228, and the plurality of through electrodes 225, and the ground wiring 265 is electrically connected to the electrode pad 222 via the through electrode 295, the wiring 228, and the plurality of through electrodes 226. Further, although not shown, for example, through electrodes 360 (see FIG. 11) connected to the signal bus 340 (see FIG. 5) are electrically connected to the electrode pad 220 via the wiring 280, the wiring 278, the wiring 266, the wiring 263, the through electrode 260, the wiring 228, and the plurality of through electrodes 224.

Further, as shown in FIG. 12 or FIG. 14, the logic chip 200 includes, as an example, the electrode pad 221, the electrode pad 222, and the electrode pad 220, and includes a power supply wiring 264 and a ground wiring 265. As shown in FIG. 14 or FIG. 5, the logic chip 200 includes, for example, one wiring 280 and three signal buses 340. The number of the electrode pad 221, the electrode pad 222, and the electrode pad 220 included in the logic chip 200, and the number of the power supply wiring 264, the ground wiring 265, and the signal bus 340 are not limited to the examples shown in FIG. 12, FIG. 14, or FIG. 5. The logic chip 200 may include two or more electrode pads 221, electrode pads 222, and electrode pads 220, and may include two or more power supply wirings 264, ground wirings 265, and signal buses 340. The number of the electrode pad 221, the electrode pad 222, and the electrode pad 220, and the number of the power supply wiring 264, the ground wiring 265, and the signal bus 340 included in the logic chip 200 can be changed as appropriate depending on the specifications, applications, and the like of the semiconductor module 10.

### SECOND EMBODIMENT

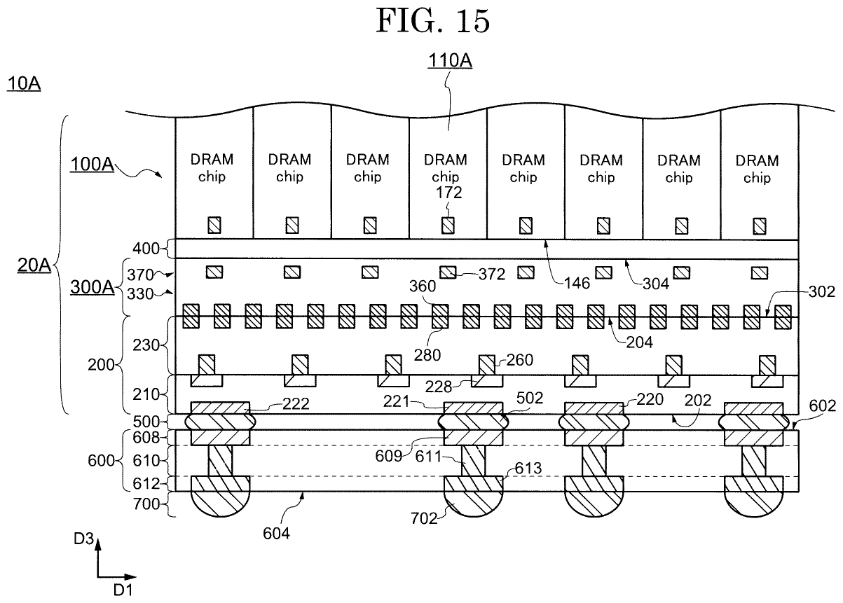

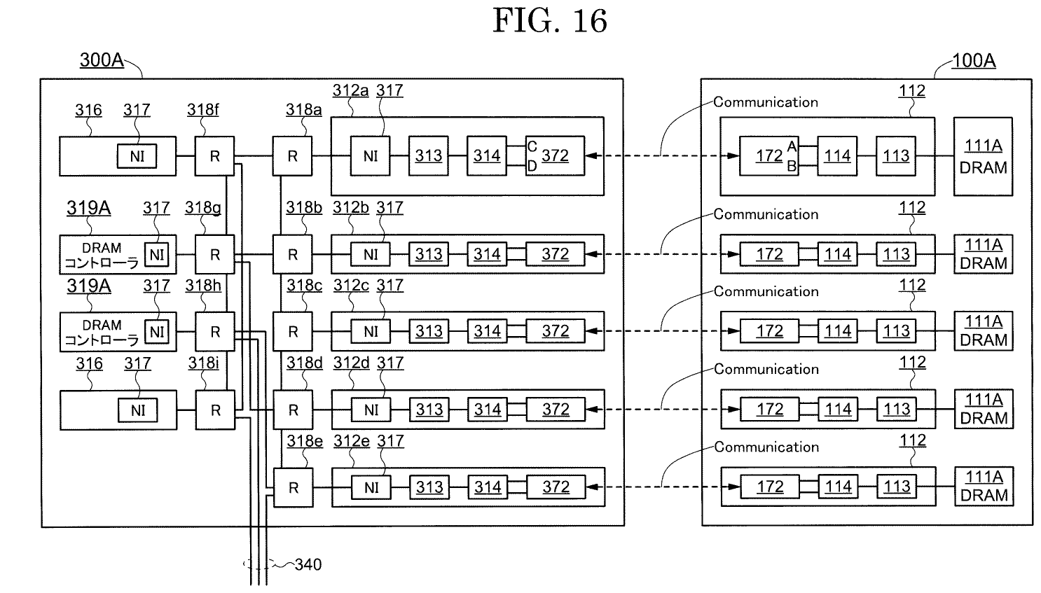

A semiconductor module 10A according to a second embodiment will be described referring to FIG. 15 and FIG. 16. FIG. 15 is a cross-sectional view showing a configuration of the semiconductor module 10A. FIG. 16 is a schematic diagram showing a configuration of a memory cube 100A and a TCI router chip 300A included in the semiconductor module 10A. Configurations that are the same as or similar to those in FIG. 1 to FIG. 14 will be described as necessary.

As shown in FIG. 15, the semiconductor module 10A includes the memory cube 100A, the TCI router chip 300A, the logic chip 200, and the adhesive layer 400. For example, a stacked body 20A is composed of the memory cube 100A, the TCI router chip 300A, the logic chip 200, and the adhesive layer 400. The semiconductor module 10A may include the bump layer 500, the package substrate 600, and the bump layer 700. The semiconductor module 10A includes a configuration in which the memory cube 100 and the TCI router chip 300 of the semiconductor module 10 are replaced with the memory cube 100A and the TCI router chip 300A. Configurations other than the memory cube 100A and the TCI router chip 300A of the semiconductor module 10A are the same as those of the semiconductor module 10. In the explanation of the semiconductor module 10A, the same configuration as that of the semiconductor module 10 will be explained as needed.

The memory cube 100A includes a configuration in which the plurality of memory chips 110 of the memory cube 100 are replaced with a plurality of DRAM chips 110A. A configuration of the DRAM chip 110A is the same as that of the memory chip 110 described in the first embodiment except that it is a DRAM. As shown in FIG. 16, the DRAM chip 110A includes a plurality of DRAMs 111A, the plurality of TCI-IOs 112, and the like.

As shown in FIG. 16, the memory cube 100A includes a configuration in which the memory module 111 of the memory cube 100 is replaced with the DRAM 111A. Configurations other than the configuration related to the DRAM 111A of the memory cube 100A are the same as those of the semiconductor module 10. The DRAM 111A is electrically connected to the TCI-IO 112 (parallel-serial conversion circuit 113).

Similar to the memory module 111, the DRAM 111A includes, for example, a function of generating a plurality of parallel signals to be transmitted and a function of controlling a plurality of received parallel signals and storing them in a memory cell array included in the DRAM 111A.

The TCI router chip 300A includes a configuration in which the memory controller 319 of the TCI router chip 300 is replaced with a DRAM controller 319A. Configurations other than the configuration related to the DRAM controller 319A of the TCI router chip 300A are the same as those of the semiconductor module 10. The DRAM controller 319A is electrically connected to the R 318. The DRAM controller 319A is, for example, an IP core.

The DRAM controller 319A, similar to the memory controller 319, includes the NI 317. In addition, the DRAM controller 319A may not include the NI 317, and the NI 317 may be located outside the DRAM controller 319A, and each of a plurality of DRAM controllers 319A may be electrically connected to the R 318 corresponding to each of the circuits via the NI 317.

IP cores, such as the plurality of TCI-IOs 312, the plurality of external IOs 316, and the plurality of DRAM controllers 319A, are electrically connected to the Rs 318 corresponding to the NI 317 of the respective IP cores. Therefore, the IP cores such as the plurality of TCI-IOs 312, the plurality of external IOs 316, and the plurality of DRAM controllers 319A are connected in a network form using the plurality of Rs 318. The plurality of Rs 318 is electrically connected using, for example, the plurality of signal buses 340.

The DRAM controller 319A is electrically connected to the logic chip 200 and the memory cube 100A via the R 318, and has a function of transmitting and receiving signals between the memory cube 100A and the logic chip 200.

The semiconductor module 10A can have the same advantageous effects as those of the semiconductor module 10. Further, the semiconductor module 10A includes the DRAM111A and the DRAM controllers 319A, has good heat conduction and excellent heat removal properties, and can perform signal transmission including a large-capacity program at a lower power consumption and at a higher speed than conventional semiconductor modules due to suppression of malfunctions caused by electromagnetic noise and heat.

### THIRD EMBODIMENT

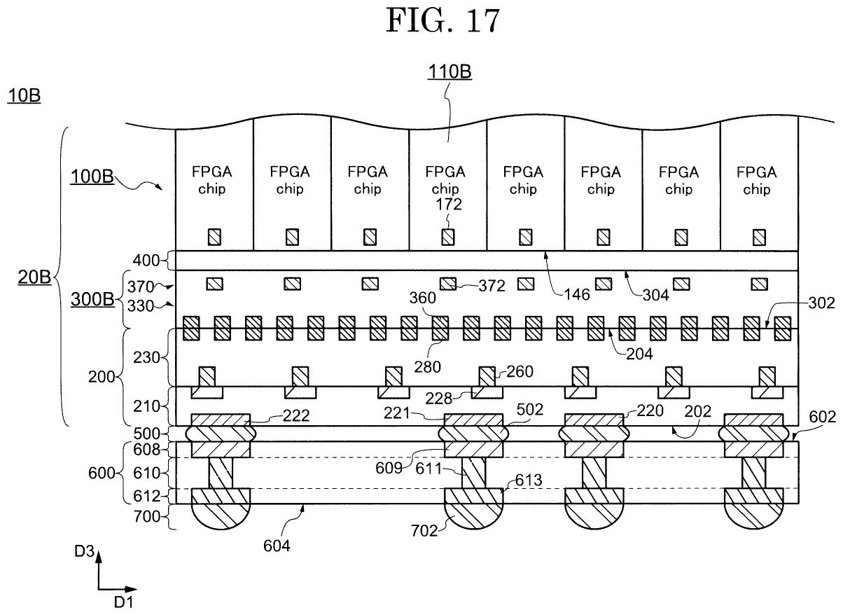

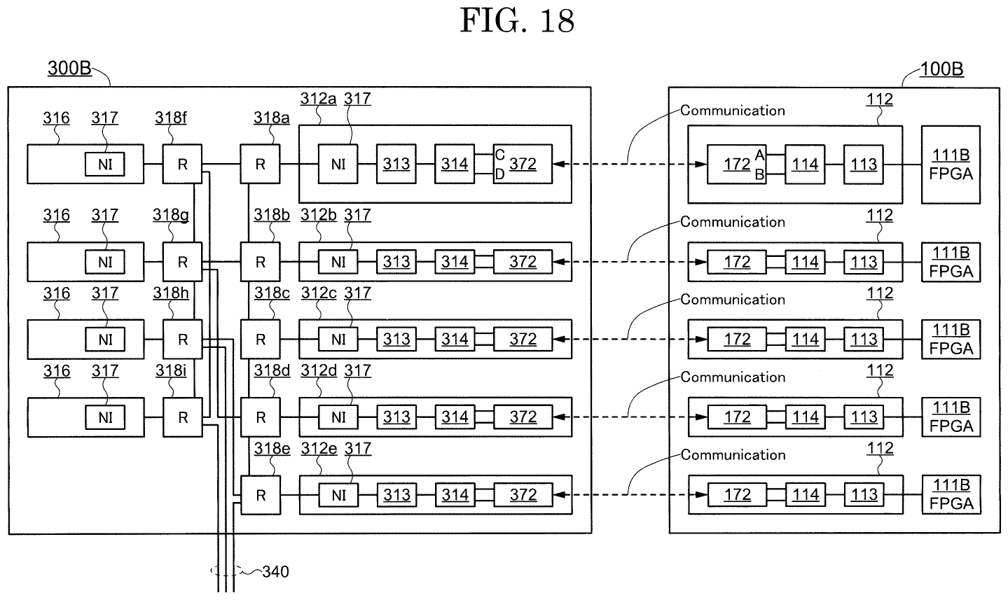

A semiconductor module 10B according to a third embodiment will be described referring to FIG. 17 and FIG. 18. FIG. 17 is a cross-sectional view showing a configuration of the semiconductor module 10B. FIG. 18 is a schematic diagram showing a configuration of a memory cube 100B and a TCI router chip 300B included in the semiconductor module 10B. Configurations that are the same as or similar to those in FIG. 1 to FIG. 16 will be described as necessary.

As shown in FIG. 17, the semiconductor module 10B includes the memory cube 100B, the TCI router chip 300B, the logic chip 200, and the adhesive layer 400. For example, a stacked body 20B is composed of the memory cube 100B, the TCI router chip 300B, the logic chip 200, and the adhesive layer 400. The semiconductor module 10B may include the bump layer 500, the package substrate 600, and the bump layer 700. The semiconductor module 10B includes a configuration in which the memory cube 100 and the TCI router chip 300 of the semiconductor module 10 are replaced with the memory cube 100B and the TCI router chip 300B. Configurations other than the memory cube 100B and TCI router chip 300B of the semiconductor module 10B are the same as those of the semiconductor module 10. In the explanation of the semiconductor module 10B, the same configuration as that of the semiconductor module 10 will be explained as needed.

The memory cube 100B includes a configuration in which the plurality of memory chips 110 of the memory cube 100 is replaced with a plurality of FPGA (Field Programmable Gate Array) chips 110B. A configuration of the FPGA chip 110B is the same as that of the memory chip 110 described in the first embodiment except that it is a FPGA. The FPGA chip 110B includes a plurality of FPGAs 111B, the plurality of TCI-IOs 112, and the like.

As shown in FIG. 18, the memory cube 100B includes a configuration in which the memory module 111 of the memory cube 100 is replaced with the FPGA 111B. Configurations other than the configuration related to the FPGA 111B of the memory cube 100B are the same as those of the semiconductor module 10. The FPGA 111B is electrically connected to the TCI-IO 112 (parallel-serial conversion circuit 113).

Similar to the memory module 111, the FPGA 111B includes, for example, a function of generating a plurality of parallel signals to be transmitted and a function of controlling a plurality of received parallel signals.

The TCI router chip 300B does not include the memory controller 319 of the TCI router chip 300. In addition, in the case where the semiconductor module 10B includes a memory circuit having a function of storing data typified by a memory, the memory controller 319 may be included. In addition, in the case where the FPGA 111B includes the storage circuitry, the memory controller 319 may be included, and the FPGA 111B may include a configuration similar to that of the memory controller 319. The FPGA chip 110B is, for example, an IP core.

IP cores, such as the plurality of TCI-IOs 312 and the plurality of external IOs 316, are electrically connected to the Rs 318 corresponding to the NI 317 of the respective IP cores. Therefore, the IP cores, such as the plurality of TCI-IOs 312 and the plurality of external IOs 316, are connected in a network form using the plurality of Rs 318. The plurality of Rs 318 are electrically connected using, for example, the plurality of signal buses 340.

The semiconductor module 10B can have the same advantageous effects as those of the semiconductor module 10. In addition, the semiconductor module 10B includes the FPGA 111B that has good heat conduction and excellent heat removal properties, suppresses malfunctions caused by electromagnetic noise and heat, and can be rewritten at a higher speed than conventional semiconductor modules.

### FOURTH EMBODIMENT

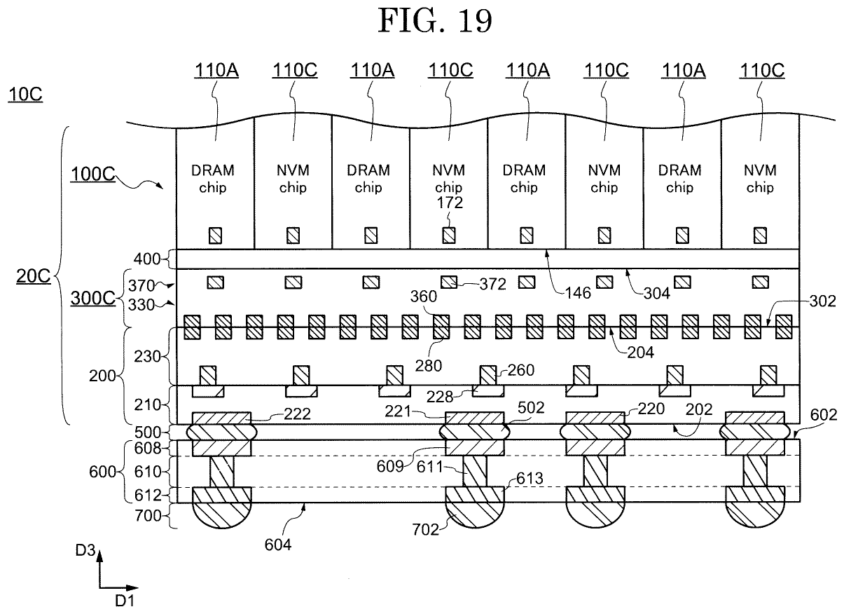

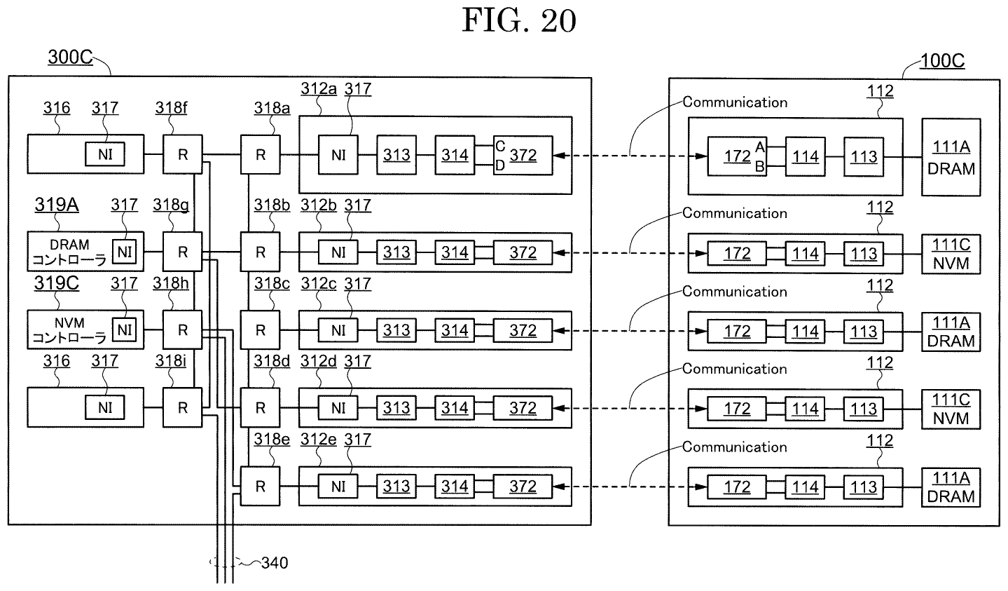

A semiconductor module 10C according to a fourth embodiment will be described referring to FIG. 19 and FIG. 20. FIG. 19 is a cross-sectional view showing a configuration of the semiconductor module 10C. FIG. 20 is a schematic diagram showing a configuration of a memory cube 100C and a TCI router chip 300C included in the semiconductor module 10C. Configurations that are the same as or similar to those in FIG. 1 to FIG. 18 will be described as necessary.

As shown in FIG. 19, the semiconductor module 10C includes the memory cube 100C, the TCI router chip 300C, the logic chip 200, and the adhesive layer 400. For example, a stacked body 20C is composed of the memory cube 100C, the TCI router chip 300C, the logic chip 200, and the adhesive layer 400. The semiconductor module 10C may include the bump layer 500, the package substrate 600, and the bump layer 700. The semiconductor module 10C includes a configuration in which the memory cube 100 and the TCI router chip 300 of the semiconductor module 10 are replaced with the memory cube 100C and the TCI router chip 300C. Configurations other than the memory cube 100C and the TCI router chip 300C of the semiconductor module 10C are the same as those of the semiconductor module 10. The same configuration as that of the semiconductor module 10 will be explained as needed, in the explanation of the semiconductor module 10C.

As shown in FIG. 19 or FIG. 20, the memory cube 100C includes a configuration in which the plurality of memory chips 110 stacked in the direction D1 of the memory cube 100 are replaced with the DRAM chips 110A and NVM (Non Volatile Memory) chips 110C alternately stacked in the direction D1. The memory cube 100C includes the DRAM chips 110A and the NVM chips 110C that are alternately stacked. Except that the memory chip is the DRAM chip 110A, the configuration is the same as that of the memory chip 110 described in the first embodiment, and a configuration of NVM chip 110C is the same as that of the memory chip 110 described in the first embodiment except that it is an NVM. The DRAM chip 110A includes the plurality of DRAMs 111A, the plurality of TCI-IOs 112, and the like, and the NVM chip 110C includes a plurality of NVMs 111C, the plurality of TCI-IOs 112, and the like.

As shown in FIG. 20, the memory cube 100C includes a configuration in which the memory module 111 of the memory cube 100 is replaced with the DRAM 111A and the NVM 111C. Configurations other than the configuration related to the DRAM 111A and the NVM 111C of the memory cube 100C are the same as those of the semiconductor module 10. The DRAM 111A is electrically connected to the TCI-IO 112 (parallel-serial conversion circuit 113), and the NVM 111C is electrically connected to the TCI-IO 112 (parallel-serial conversion circuit 113) that differs from TCI-IO 112 (parallel-serial conversion circuit 113) connected to the DRAM 111A.

Similar to the memory module 111, the DRAM 111A includes, for example, a function of generating a plurality of parallel signals to be transmitted and a function of controlling a plurality of received parallel signals and storing them in a memory cell array included in the DRAM 111A. Similar to the memory module 111, the NVM 111C includes, for example, a function of generating a plurality of parallel signals to be transmitted and a function of controlling a plurality of received parallel signals and storing them in a memory cell array included in the NVM 111C.

The TCI router chip 300C includes a configuration in which the memory controller 319 of the TCI router chip 300 is replaced with the DRAM controller 319A and an NVM controller 319C. Configurations other than the configuration related to the DRAM controller 319A and the NVM controller 319C of the TCI router chip 300C are the same as those of the semiconductor module 10. The DRAM controller 319A is electrically connected, for example, to the R 318g, and the NVM controller 319C is electrically connected, for example, to the R 318h. The DRAM controller 319A and the NVM controller 319C are, for example, IP cores.

The DRAM controller 319A and the NVM controller 319C include the NI 317 as well as the memory controller 319. In addition, the DRAM controller 319A and the NVM controller 319C may not include the NI 317, and the NI 317 may be located outside the DRAM controller 319A and the NVM controller, and the DRAM controller 319A and the NVM controller 319C may be electrically connected to the Rs 318 corresponding to the respective circuits via the NI 317.

IP cores, such as the plurality of TCI-IOs 312, the plurality of external IOs 316, the DRAM controller 319A, and the NVM controller 319C, are electrically connected to the Rs 318 corresponding to the NI 317 of the respective IP cores. Therefore, the IP cores such as the plurality of TCI-IOs 312, the plurality of external IOs 316, the plurality of DRAM controllers 319A, and the NVM controller 319C are connected in a network form using the plurality of Rs 318. The plurality of Rs 318 is electrically connected using, for example, the plurality of signal buses 340.

The DRAM controller 319A and the NVM controller 319C are electrically connected to the logic chip 200 and the memory cube 100C via the R 318, and have a function of transmitting and receiving signals between the memory cube 100C and the logic chip 200.

The semiconductor module 10C can have the same advantageous effects as those of the semiconductor module 10. Further, the semiconductor module 10C includes the DRAM 111A and the DRAM controller 319A that have good thermal conductivity and excellent heat removal properties and can suppress malfunctions caused by electromagnetic noise and heat, and can perform signal transmission including a large-capacity program at a lower power consumption and at a higher speed than that of a conventional semiconductor module. Further, the semiconductor module 10C includes the NVM 111C and the NVM controller 319C that are excellent in heat conduction, excellent in heat removal properties, and can suppress malfunctions caused by electromagnetic noise and heat, and can execute signal transmission including data of a large capacity at a higher speed with lower power consumption than that of a conventional semiconductor module, and can store data of a large capacity in a nonvolatile manner.

### FIFTH EMBODIMENT

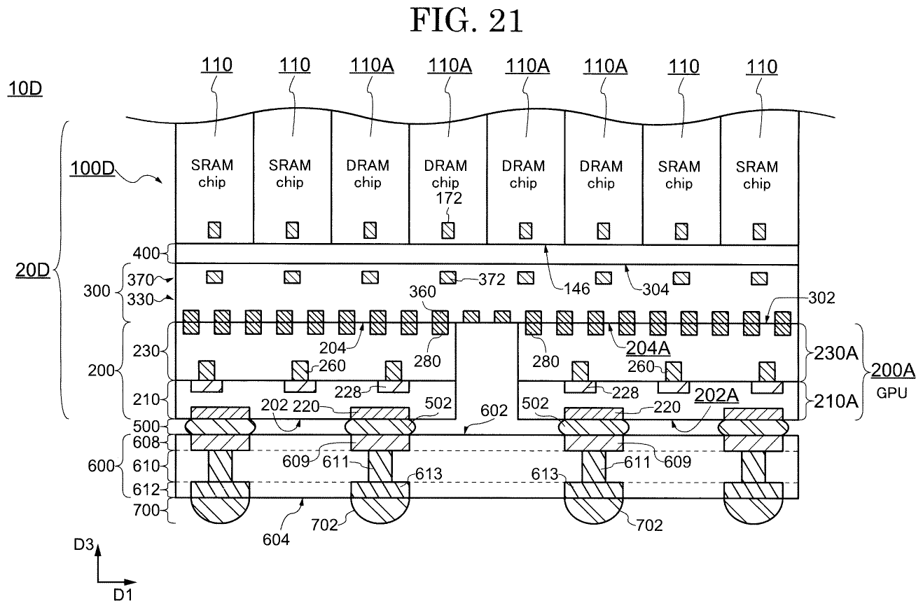

A semiconductor module 10D according to a fifth embodiment will be described referring to FIG. 21. FIG. 21 is a cross-sectional view showing a configuration of the semiconductor module 10D. Configurations that are the same as or similar to those in FIG. 1 to FIG. 20 will be described as necessary.

As shown in FIG. 21, the semiconductor module 10D includes a memory cube 100D, the TCI router chip 300, the logic chip 200, a GPU (Graphics Processing Unit) 200A, and the adhesive layer 400. For example, a stacked body 20D is constituted by the memory cube 100D, the TCI router chip 300, the logic chip 200, and the adhesive layer 400. The semiconductor module 10D may include the bump layer 500, the package substrate 600, and the bump layer 700. The semiconductor module 10D includes a configuration in which the memory cube 100 of the semiconductor module 10 is replaced with the memory cube 100D, and the TCI router chip 300 in which the logic chips 200 of the semiconductor module 10 are stacked (bonded) is replaced with the TCI router chip 300 in which the logic chip 200 and the GPU 200A are stacked (bonded). Other configurations of the semiconductor module 10D are the same as those of the semiconductor module 10 or the semiconductor module 10A. Configurations similar to those of the semiconductor module 10 and the semiconductor module 10A will be explained as needed, in the explanation of the semiconductor module 10D.

The plurality of memory chips 110 stacked in the direction D1 of the memory cube 100 in the semiconductor module 10, are one type of memory chip (SRAM). On the other hand, as shown in FIG. 21, in the memory cube 100D, the plurality of memory chips stacked in the direction D1 are two types: the memory chip 110 and the DRAM chip 110A. The memory chip 110 is a SRAM. The memory cube 100D includes a configuration in which two memory chips 110, four DRAM chips 110A, and two memory chips 110 are stacked in this order in the direction D1. The order of stacking of the memory chip 110 and the DRAM chip 110A in the memory cube 100D is not limited to that shown in FIG. 21. The order of stacking of the memory chip 110 and the DRAM chip 110A of the memory cube 100D can be appropriately changed according to the specifications, applications, and the like of the semiconductor module 10D. The configuration of the DRAM chip 110A is the same as that of the memory chip 110 described in the second embodiment except that it is the DRAM.

As described above, the logic chip 200 and the GPU 200A are laminated (bonded) to the TCI router chip 300. The stacking (bonding) of the logic chip 200 and the TCI router chip 300 is as described in “1-1-1. Overall Configuration of the Semiconductor Module 10”.

The GPU 200A includes a configuration in which the lower wiring layer 210A and a transistor layer 230A are stacked in this order in the direction D3, and includes a first surface 202A parallel to the direction D1 and the direction D2, and a second surface 204A opposite to the first surface 202A. The first surface 202A is an exposed surface of the lower wiring layer 210A. The second surface 204A is an exposed surface of the transistor layer 230A. The lower wiring layer 210A and the transistor layer 230A have the same configuration and function as the lower wiring layer 210 and the transistor layer 230 described in the first embodiment. Therefore, the configuration of the lower wiring layer 210A and the transistor layer 230A will be described as needed. In addition, the transistor layer 230A includes the plurality of wirings 280, the plurality of wirings 280 is exposed to the second surface 204A, the lower wiring layer 210A includes a plurality of electrode pads 220, and the plurality of electrode pads 220 are exposed to the first surface 202A. In addition, the GPU 200A includes the same configuration and function as those of a GPU used in the technical field of the semiconductor module. For example, the GPU 200A is a logic chip that has the same configuration and function as the logic chip 200 and specializes in image processing. The GPU 200A may be referred to as a second logic chip.

Further, similar to the logic chip 200, the GPU 200A is face-up mounted on the package substrate 600 while the first surface 202A of the GPU 200A is arranged on the package substrate 600.

Similar to the logic chip 200 of the semiconductor module 10, the first surface 302 of the TCI router chip 300 of the semiconductor module 10D is a surface facing the second surface 204A of the GPU 200A and contacting the second surface 204A of the GPU 200A. Similar to the logic chip 200 of the semiconductor module 10, each of the plurality of through electrodes 360 exposed on the first surface 302 of the TCI router chip 300 is bonded to a corresponding plurality of wirings 280 among the plurality of wirings 280 exposed on the second surface 204, and the GPU 200A is electrically connected to the TCI router chip 300.

Further, similar to the logic chip 200 of the semiconductor module 10, each of the plurality of wirings 609 exposed on the first surface 602 of the package substrate 600 is electrically connected to each of the plurality of electrode pads 220 exposed on the first surface 202A of the GPU 200A by using the bump 502, and each of the plurality of wirings 613 exposed on the second surface 604 of the package substrate 600 is connected to the external substrate, the external circuit, and the like by using the bump 702.

In addition, the TCI router chip 300 may include the plurality of through electrodes 360 that is not connected to the logic chip 200 and the GPU 200A.

The DRAM controller 319A and the NVM controller 319C are electrically connected to the logic chip 200 and the memory cube 100D via the R 318, and have a function of transmitting and receiving signals between the memory cube 100D and the logic chip 200.

The semiconductor module 10D can have the same advantageous effects as those of the semiconductor module 10. Further, the semiconductor module 10D includes a SRAM chip and the DRAM chip 110A that have good thermal conductivity and excellent heat removal properties and can suppress malfunctions caused by electromagnetic noise and heat, and can perform signal transmission including a large-capacity program and signal (data) at a higher speed with lower power consumption than conventional semiconductor modules. Further, the semiconductor module 10D includes a configuration in which heat conduction is good, heat removal properties are excellent, and malfunctions caused by electromagnetic noise and heat are suppressed, and signal transmission including signals (data) associated with image processing can be executed at low power consumption at high speed.

### SIXTH EMBODIMENT

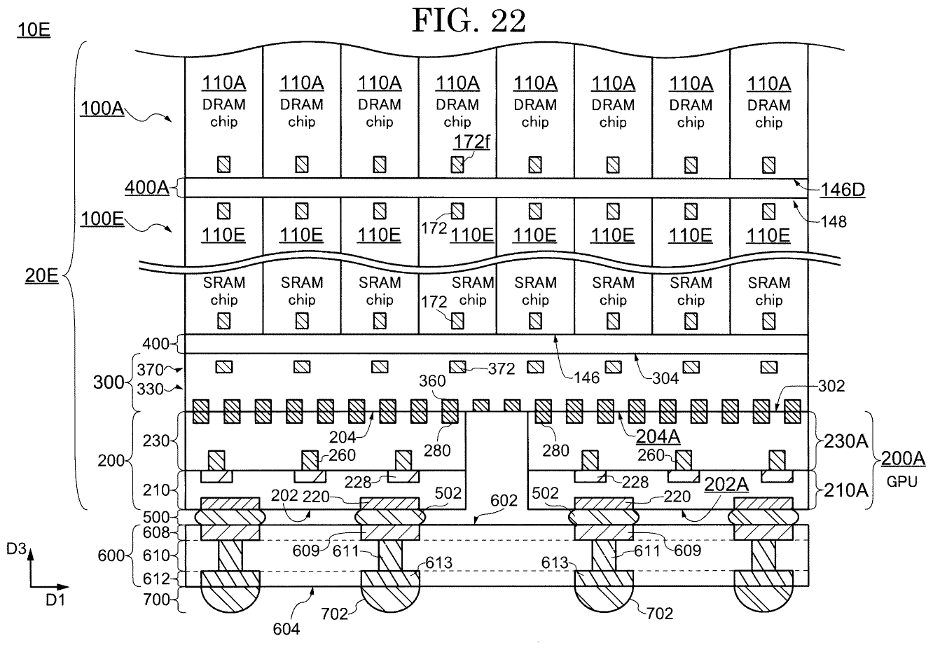

A semiconductor module 10E according to a sixth embodiment will be described referring to FIG. 22. FIG. 22 is a cross-sectional view showing a configuration of the semiconductor module 10E. Configurations that are the same as or similar to those in FIG. 1 to FIG. 21 will be described as necessary.

As shown in FIG. 22, the semiconductor module 10E includes the memory cube 100A, a memory cube 100E, the TCI router chip 300, the logic chip 200, the GPU 200A, an adhesive layer 400A, and the adhesive layer 400. For example, a stacked body 20E is composed of the memory cube 100A, the memory cube 100E, the TCI router chip 300, the logic chip 200, the GPU 200A, the adhesive layer 400A, and the adhesive layer 400. The semiconductor module 10E may include the bump layer 500, the package substrate 600, and the bump layer 700. The semiconductor module 10E includes a configuration in which the memory cube 100D of the semiconductor module 10D is replaced with a configuration in which the memory cube 100A and the memory cube 100E are connected by the adhesive 400A. Other configurations of the semiconductor module 10E are the same as those of the semiconductor module 10D. In the explanation of the semiconductor module 10E, a configuration similar to that of the semiconductor module 10D will be explained as needed.

The memory cube arranged in the direction D3 of the semiconductor module 10D is one stage of the memory cube 100D. Meanwhile, the memory cubes arranged in the direction D3 of the semiconductor module 10E are two stages of the memory cube 100A and the memory cube 100E. Although the memory cube arranged in the direction D3 of the semiconductor module 10E is, for example, two stages, the memory cube arranged in the direction D3 of the semiconductor module 10E may be three or more stages. The number of stages of the memory cube arranged in the direction D3 of the semiconductor module 10E is appropriately selected depending on the specifications and applications of the semiconductor module 10E, the number of IP cores included in the semiconductor module 10, and the like.

The memory cube 100A has the same configuration as that of the memory cube 100A according to the second embodiment. In addition, reference signs of the plurality of inductors of the DRAM chip 110A included in the memory cube 100A are denoted as an inductor 172f in order to avoid duplication with the plurality of inductors 172 included in the memory chip 110. The inductor 172f includes a configuration and a function similar to those of the inductor 172. A plurality of inductors 172f is arranged close to the second side surface 146 and extends in the direction D2.

The memory cube 100E includes a configuration in which the plurality of memory chips 110 included in the memory cube 100A according to the second embodiment are replaced with a plurality of memory chips 110E. The memory chip 110E differs from the memory chip 110 in that the plurality of inductors 172 included in the memory chip 110 is arranged close to both sides of the second side surface 146 and the fourth side surface 148 and extend in the direction D2. In addition, the configuration and the function of the inductor 172 included in the memory chip 110E are the same as the configuration and the function of the inductor 172 included in the memory chip 110.

The adhesive layer 400A is arranged between the fourth side 148 of the memory cube 100E and the second side 146D of the memory cube 100A to adhere the memory cube 100E to the memory cube 100A. The adhesive layer 400A is formed of the same material as the adhesive layer 400.

Each of the plurality of inductors 172f is magnetically coupled to the corresponding inductor 172 among the plurality of inductors 172 arranged close to the fourth side surface 148 so that the inductors can communicate with each other in a one-to-one manner in a contactless manner. In addition, each of the plurality of inductors 172 arranged close to the second side surface 146 side is magnetically coupled to a corresponding inductor 372 among the plurality of inductors 372 arranged close to the second side surface 304 side of the TCI router chip 300, so that the inductors can communicate with each other in a one-to-one manner in a contactless manner.

The semiconductor module 10E can have the same advantageous effects as those of the semiconductor module 10. Further, the semiconductor module 10E may further include a configuration in which memory cubes in which memory chips are stacked in the direction D1 are arranged in multiple stages in the direction D3, and the memory capacity may be further increased.

Various configurations of the semiconductor modules 10, 10A, 10B, 10C, 10D, and 10E exemplified as an embodiment of the present invention can be appropriately replaced as long as they do not conflict with each other and without departing from the spirit of the present invention. Further, various configurations of the semiconductor modules 10, 10A, 10B, 10C, 10D, and 10E exemplified as an embodiment of the present invention can be appropriately combined as long as they do not conflict with each other and without departing from the spirit of the present invention. Further, technical matters common to the respective embodiments are included in the respective embodiments without explicit description. Further, any semiconductor module that a person skilled in the art may add, delete, or modify the design of components, or add, omit, or modify processes based on the semiconductor module disclosed in this specification and drawings, is included within the scope of the present invention as long as it includes the gist of the present invention.

It is to be understood that the present invention provides other effects that are different from the effects provided by the aspects of the embodiments disclosed herein, and those that are obvious from the description herein or that can be easily predicted by a person skilled in the art.

What is claimed is:

1. A semiconductor module comprising:
a first logic chip including a first surface parallel to a first direction and a second direction intersecting the first direction, and a second surface parallel to the first surface;
a first semiconductor chip including a third surface parallel to the second surface and a fourth surface parallel to the third surface, the third surface being arranged on the second surface, and electrically connected to the first logic chip; and
a first semiconductor cube including a plurality of second semiconductor chips stacked in the first direction, and arranged on the fourth surface, wherein
each of the plurality of second semiconductor chips includes a first inductor arranged in a third direction perpendicular to the first and second directions,
the first semiconductor chip includes a plurality of routers and a second inductor arranged parallel to the fourth surface,
a plurality of circuits in the first logic chip and a plurality of circuits in the first semiconductor chip are connected using the plurality of routers, and
the plurality of second semiconductor chips, the first logic chip, and the first semiconductor chip are configured to enable contactless communication using the first inductor and the second inductor.

2. The semiconductor module of claim 1, wherein
the first logic chip includes a first electrode on the second surface,
the first semiconductor chip includes a second electrode, and
the second electrode is configured so as to join the first electrode by fusion bonding on the third surface.

3. The semiconductor module of claim 1, wherein
each of the plurality of routers includes a switch.

4. The semiconductor module of claim 1, wherein
the plurality of second semiconductor chips includes at least one type of memory chip, and
the first semiconductor chip includes a memory controller configured to control the at least one type of memory chip.

5. The semiconductor module of claim 1, wherein
the plurality of second semiconductor chips includes an FPGA chip configured to be controllable using the first logic chip.

6. The semiconductor module of claim 1, wherein
the first logic chip includes a plurality of wiring layers provided on the first surface side, is electrically connected to a package substrate via a plurality of bumps electrically connected to the plurality of wiring layers, and receives a control signal and a power supply voltage from the package substrate.

7. The semiconductor module of claim 1, wherein
the first logic chip is connected to the third surface of the first semiconductor chip in a face-up connection, and
the first semiconductor chip is electrically connected to the first semiconductor cube in a face-up connection.

8. The semiconductor module of claim 4, further comprising:
a second logic chip different from the first semiconductor chip, the second semiconductor chip, and the first logic chip, wherein
the second logic chip includes a sixth surface parallel to the first direction and the second direction and a seventh surface parallel to the sixth surface, and is arranged spaced apart from the first logic chip in the first direction and the second direction, and
the sixth surface is in contact with the third surface.

9. The semiconductor module of claim 1, further comprising
a second semiconductor cube on which a plurality of third semiconductor chips different from the first semiconductor chip, the second semiconductor chip, and the first logic chip are arranged in the first direction,
wherein the second semiconductor cube is arranged on a fifth surface of the first semiconductor cube opposite the fourth surface along the third direction.
